(19) United States
(12) Patent Application Publication
(10) Pub. No.: US 2025/0194113 A1
(43) Pub. Date: Jun. 12, 2025

(54) SEMICONDUCTOR DEVICE AND METHOD FOR FABRICATING THE SAME

(71) Applicant: SK hynix Inc., Gyeonggi-do (KR)

(72) Inventors: Seung Hwan KIM, Gyeonggi-do (KR); Sung Mean PARK, Gyeonggi-do (KR)

(21) Appl. No.: 18/963,495

(22) Filed: Nov. 28, 2024

(30) Foreign Application Priority Data
Dec. 11, 2023 (KR) 10-2023-0178842
Nov. 25, 2024 (KR) 10-2024-0169960

(51) Int. Cl. H10B 80/00; H01L 21/768; H01L 23/00; H01L 23/498; H01L 23/528

(52) U.S. Cl. CPC H10B 80/00; H01L 21/76877; H01L 23/49827; H01L 23/49838; H01L 23/5283; H01L 24/08; H01L 2224/08258; H01L 2924/1434

(57) ABSTRACT

Disclosed are a semiconductor device including highly integrated memory cells, and a method for fabricating the semiconductor device. A semiconductor device includes a memory cell array disposed over the peripheral circuit region; a dummy region including a dummy stack that is spaced apart horizontally from the memory cell array; a peripheral circuit region disposed at a lower level than the memory cell array and dummy region; a stack level plug passing through the dummy stack; and a stack level spacer formed on a sidewall of the stack level plug.

### CROSS-REFERENCE TO RELATED APPLICATIONS

The present application claims priority under 35 U.S.C 119(a) to Korean Patent Application No. 10-2023-0178842 and No. 10-2024-0169960, respectively filed on Dec. 11, 2023 and Nov. 25, 2024, which is incorporated herein by reference in its entirety.

### BACKGROUND

### 1. Field

Embodiments of the present disclosure relate to a semiconductor device, and more particularly, to a semiconductor device including three-dimensional (3D) memory cells, and a method for fabricating the semiconductor device.

### 2. Description of the Related Art

In order to cope with the demands for large capacity and miniaturization of memory devices, technology for providing a three-dimensional (3D) memory device in which a plurality of memory cells are stacked is disclosed recently.

### SUMMARY

Embodiments of the present disclosure are directed to a semiconductor device including highly integrated memory cells, and a method for fabricating the semiconductor device.

In accordance with an embodiment of the present disclosure, a semiconductor device includes a memory cell array disposed over the peripheral circuit region; a dummy region including a dummy stack that is spaced apart horizontally from the memory cell array; a peripheral circuit region disposed at a lower level than the memory cell array and dummy region; a stack level plug passing through the dummy stack; and a stack level spacer formed on a sidewall of the stack level plug.

In accordance with another embodiment of the present disclosure, a method for fabricating a semiconductor device includes forming a memory cell array and a dummy stack over a first substrate, the memory cell array and the dummy stack spaced apart from each other horizontally; forming a stack level contact hole to penetrate the dummy stack; forming a stack level spacer on a sidewall of the stack level contact hole; and forming a stack level plug over the stack level spacer to fill the stack level contact hole.

In accordance with an embodiment of the present disclosure, a semiconductor device includes a memory cell array disposed over a first substrate; a second substrate including a front side and a back side and flipped to face the memory cell array; a peripheral circuit formed on the front side of the second substrate; and a back-side interconnection structure passing through the second substrate from the back side of the second substrate and coupled to the peripheral circuit. The back-side interconnection structure includes a power interconnection line embedded in the second substrate; a power contact plug coupled to a bottom surface of the power interconnection line; a power via coupled to a top surface of the power interconnection line; and a post multi-layer level interconnection coupled to a top surface of the power via. The semiconductor device may further include a power level spacer formed on the sidewall of the power interconnection line and the power via. The power interconnection line is embedded in the second substrate, and sidewalls of the power interconnection line are fully surrounded by and isolated from the second substrate by the power level spacer. The semiconductor device may further include a first bonding pad coupled to the memory cell array; and a second bonding pad coupled to the peripheral circuit. The peripheral circuit includes a plurality of control circuits for driving the memory cell array. The memory cell array includes a plurality of memory cells that are stacked vertically, and wherein each of the memory cells includes a horizontal layer that is oriented horizontally; a first conductive line that is oriented vertically while being coupled to a first side of the horizontal layer; a second conductive line that is oriented horizontally while crossing the horizontal layer; and a data storage element coupled to a second side of the horizontal layer.

In accordance with another embodiment of the present disclosure, a semiconductor device includes a peripheral circuit region; a memory cell array including a vertical conductive line disposed over the peripheral circuit region, a plurality of data storage elements, and a common plate line commonly coupled to the data storage elements. The semiconductor device further includes a substrate formed over an upper portion of the common plate line; a nano-through hole configured to penetrate the substrate to expose an upper portion of the common plate line; a nano level spacer formed on a sidewall of the nano-through hole; a nano-through silicon via configured to fill the nano-through hole over the nano level spacer; an upper level interconnection over the nano-through silicon via; a lower level interconnection coupled to a lower portion of the vertical conductive line; a first bonding pad coupled to the lower level interconnection; and a second bonding pad coupled to the first bonding pad while being coupled to the peripheral circuit region. The semiconductor device may include a dummy region including a dummy stack that is horizontally spaced apart from the memory cell array; a stack level plug configured to penetrate the dummy stack; and a stack level spacer formed on a sidewall of the stack level plug.

In accordance with another embodiment of the present disclosure, a semiconductor device includes a memory cell array disposed over a front side of a first substrate; a back-side interconnection structure disposed at a higher level than the memory cell array; a second substrate having a front side facing the memory cell array and a back side facing the back-side interconnection structure; a control circuit including one or more transistors disposed over the front side of the second substrate; and a multi-level metal line including one or more metal lines coupled to the control circuit. The back-side interconnection structure may include a power interconnection line embedded inside on the side of the front side of the second substrate; a power via configured to penetrate the back side of the second substrate to be coupled to the power interconnection line; a power contact plug coupled to the power interconnection line and the control circuit; and a power level spacer formed on the sidewalls of the power interconnection line and the power via.

In accordance with an embodiment of the present invention, a semiconductor device may include a first substrate; a memory cell array including memory cells that are vertically stacked over the first substrate; a second substrate including a front side facing the memory cell array and a back side at a higher level than the front side, and including a plurality of control circuits for controlling the memory cells; a back-side power distribution network passing through the second substrate and supplies power to the control circuits from the back side of the second substrate, wherein the back-side power distribution network may include a buried power rail embedded in the front side of the second substrate; a nano-through silicon via passing through the back side of the second substrate and coupled to the buried power rail; a power level spacer formed on a sidewall of the nano-through silicon via and the buried power rail; and a buried power rail via disposed on the front side of the second substrate and coupled to the buried power rail.

### BRIEF DESCRIPTION OF THE DRAWINGS

FIG. 1A is a schematic perspective view illustrating a memory cell in accordance with an embodiment of the present disclosure.

FIG. 1B is a schematic cross-sectional view illustrating the memory cell shown in FIG. 1A.

FIG. 1C is a plan view illustrating a switching element shown in FIG. 1A.

FIG. 1D is a schematic cross-sectional view illustrating a memory cell in accordance with another embodiment of the present disclosure.

FIG. 2A is a schematic plan view illustrating a semiconductor device in accordance with an embodiment of the present disclosure.

FIG. 2B is a schematic perspective view illustrating a memory cell array MCA shown in FIG. 2A.

FIG. 2C is a schematic cross-sectional view taken along a line A-A′ shown in FIG. 2A.

FIG. 2D is a schematic cross-sectional view taken along a line B-B′ shown in FIG. 2A.

FIG. 3 is a schematic cross-sectional view illustrating a semiconductor device 200 in accordance with another embodiment of the present disclosure.

FIGS. 4 to 22 illustrate a method for fabricating a semiconductor device in accordance with an embodiment of the present disclosure.

FIGS. 23 to 27 illustrate a method for fabricating a pad portion in accordance with an embodiment of the present disclosure.

FIGS. 28 to 33 illustrate a method for fabricating the semiconductor device shown in FIG. 3.

FIGS. 34 to 36 illustrate a method for fabricating a semiconductor device in accordance with another embodiment of the present disclosure.

FIGS. 37 to 39 are perspective views illustrating a semiconductor device in accordance with another embodiment of the present disclosure.

FIG. 40 is a cross-sectional view illustrating a memory cell array in accordance with another embodiment of the present disclosure.

FIGS. 41 to 45 illustrate a semiconductor device in accordance with another embodiment of the present disclosure.

### DETAILED DESCRIPTION

Various embodiments of the present disclosure will be described below in more detail with reference to the accompanying drawings. The embodiments of the present disclosure may, however, be embodied in different forms and should not be construed as limited to the embodiments set forth herein. Rather, these embodiments are provided so that this disclosure will be thorough and complete, and will fully convey the scope of the present disclosure to those skilled in the art. Throughout this disclosure, like reference numerals refer to like parts throughout the various figures and embodiments of the present disclosure.

Hereinafter, the various embodiments of the present disclosure will be described in detail with reference to the attached drawings.

The drawings are not necessarily to scale and in some instances, proportions may have been exaggerated to clearly illustrate features of the embodiments of the present disclosure. When a first layer is referred to as being ‘on’ a second layer or ‘on’ a substrate, it not only refers to a case where the first layer is formed directly on the second layer or the substrate but also a case where a third layer exists between the first layer and the second layer or the substrate.

The following embodiments of the present disclosure relate to three-dimensional memory cells, which may increase the memory cell density and reduce the parasitic capacitance by vertically stacking memory cells.

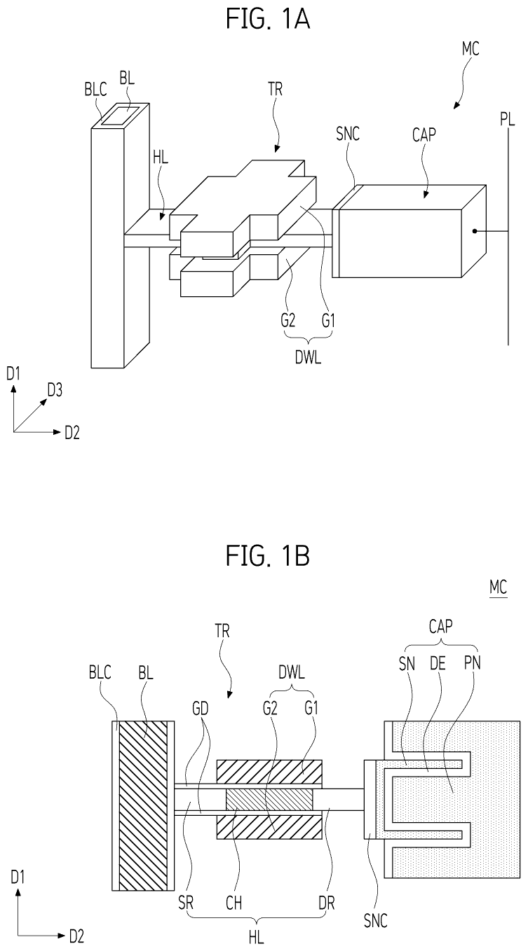

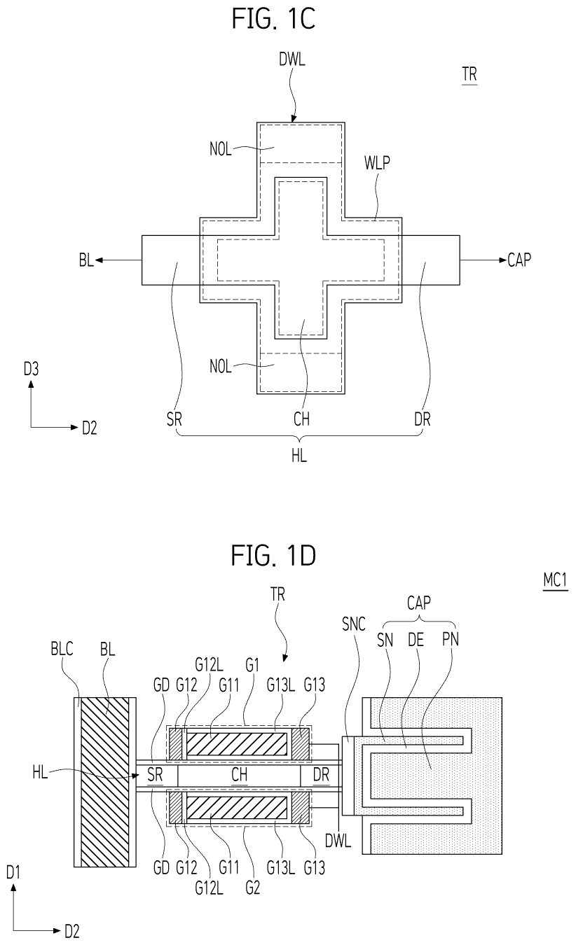

FIG. 1A is a schematic perspective view illustrating a memory cell MC in accordance with an embodiment of the present disclosure. FIG. 1B is a schematic cross-sectional view illustrating the memory cell MC of FIG. 1A. FIG. 1C is a plan view illustrating a switching element of FIG. 1A.

Referring to FIGS. 1A to 1C, the memory cell MC may include a first conductive line BL, a switching element TR, and a data storage element CAP.

The first conductive line BL may be vertically oriented in a first direction D1. The first conductive line BL may include a bit line. The first conductive line BL may be referred to as a vertical conductive line, a vertically-oriented bit line, a vertically-extending bit line, or a pillar-shaped bit line. The first conductive line BL may include a conductive material. The first conductive line BL may include a silicon-based material, a metal-based material, or a combination thereof. The first conductive line BL may include polysilicon, a metal, a metal nitride, a metal silicide, or a combination thereof. The first conductive line BL may include polysilicon, titanium nitride, tungsten, or a combination thereof. For example, the first conductive line BL may include a stack of titanium nitride and tungsten (TiN/W).

The switching element TR may have a function of controlling the voltage (or current) supply to the data storage element CAP in a data write operation and a data read operation for the data storage element CAP. The switching element TR may include a horizontal layer HL, an inter-level dielectric layer GD, and a second conductive line DWL. The second conductive line DWL may include a horizontal conductive line or a horizontal word line. The horizontal layer HL may include an active layer. The switching element TR may include a transistor, and in this case, the second conductive line DWL may serve as a gate electrode. The switching element TR may also be referred to as an access element or a selection element. The second conductive line DWL may be referred to as a horizontal gate electrode or a horizontal word line.

The horizontal layer HL may extend in a second direction D2 intersecting with the first direction D1. The second conductive line DWL may extend in a third direction D3 intersecting with the first direction D1 and the second direction D2. The first direction D1 may be a vertical direction, the second direction D2 may be a first horizontal direction, and the third direction D3 may be a second horizontal direction. The horizontal layer HL may extend in the first horizontal direction (i.e., the second direction D2), and the second conductive line DWL may extend in the second horizontal direction (i.e., the third direction D3).

The horizontal layer HL may be horizontally oriented in the second direction D2 from the first conductive line BL. The second conductive line DWL may have a double structure. For example, the second conductive line DWL may include an upper horizontal line G1 and a lower horizontal line G2 that are facing each other with a horizontal layer HL interposed between them. An inter-level dielectric layer GD may be formed on an upper surface and a lower surface of the horizontal layer HL. The upper horizontal line G1 may be disposed over the horizontal layer HL, and the lower horizontal line G2 may be disposed below the horizontal layer HL. The second conductive line DWL may include a pair of the upper horizontal line G1 and the lower horizontal line G2. In the second conductive line DWL, the same driving voltage may be applied to the upper horizontal line G1 and the lower horizontal line G2. For example, the upper horizontal line G1 and the lower horizontal line G2 may form a pair to be coupled to a single memory cell MC. According to another embodiment of the present disclosure, different driving voltages may be applied to the upper horizontal line G1 and the lower horizontal line G2. In this case, one horizontal line among the upper horizontal line G1 and the lower horizontal line G2 may serve as a back gate or a shield gate.

Referring back to FIG. 1C, each of the upper horizontal line G1 and the lower horizontal line G2 may have a width in the second direction D2, for example, a width of an overlapping portion that overlaps with the horizontal layer HL, to be greater than a width of a non-overlapping portion that does not overlap with the horizontal layer HL. Due to this width difference, the second conductive line DWL may have a notch-shaped sidewall. The second conductive line DWL may include a channel overlapping portion WLP and a channel non-overlapping portion NOL. The channel overlapping portion WLP may refer to a portion that overlaps with the channel CH of the horizontal layer HL. The channel non-overlapping portion NOL may refer to a portion that does not overlap with the horizontal layer HL. The channel overlapping portion WLP may have a cross shape or a rhombus shape.

From the perspective of a top view, the horizontal layer HL may have a cross shape or a rhombus shape. According to another embodiment of the present disclosure, the side surfaces of the horizontal layer HL may have a bent shape or a rounded shape.

The horizontal layer HL may include a semiconductor material. For example, the horizontal layer HL may include polysilicon, monocrystalline silicon, germanium, or silicon-germanium. According to another embodiment of the present disclosure, the horizontal layer HL may include an oxide semiconductor material. For example, the oxide semiconductor material may include Indium Gallium Zinc Oxide (IGZO). According to another embodiment of the present disclosure, the horizontal layer HL may include a conductive metal oxide.

The upper surface and the lower surface of the horizontal layer HL may have a flat surface. The upper surface and the lower surface of the horizontal layer HL may be parallel to each other in the second direction D2.

The horizontal layer HL may include a channel CH, a first doped region SR between the channel CH and the first conductive line BL, and a second doped region DR between the channel CH and the data storage element CAP. When the horizontal layer HL is formed of an oxide semiconductor material, the channel CH may be formed of an oxide semiconductor material, and the first and second doped regions SR and DR may be omitted. The horizontal layer HL may also be referred to as an active layer or a thin-body. The channel CH and the channel overlapping portion WLP of the second conductive line DWL may overlap with each other. The channel CH may have a cross shape or a rhombus shape. The size of the channel overlapping portion WLP of the second conductive line DWL may be greater than that of the channel CH. The channel overlapping portion WLP of the second conductive line DWL may fully overlap with the channel CH.

The first doped region SR and the second doped region DR may be doped with impurities of the same conductive type. The first doped region SR and the second doped region DR may be doped with an N-type conductive impurity or a P-type conductive impurity. The first doped region SR and the second doped region DR may include at least one impurity selected from the group including arsenic (As), phosphorus (P), boron (B), indium (In), and combinations thereof. The first doped region SR may be coupled to the first conductive line BL, and the second doped region DR may be coupled to the data storage element CAP. The first and second doped regions SR and DR may be referred to as first and second source/drain regions, respectively.

The inter-level dielectric layer GD may be disposed between the horizontal layer HL and the second conductive line DWL. The inter-level dielectric layer GD may also be referred to as a gate dielectric layer. The inter-level dielectric layer GD may also be referred to as a horizontal layer side dielectric layer. The inter-level dielectric layer GD may include silicon oxide, silicon nitride, a metal oxide, a metal oxynitride, a metal silicate, a high-k material, a ferroelectric material, an anti-ferroelectric material, or a combination thereof. The inter-level dielectric layer GD may include SiO₂, Si₃N₄, HfO₂, Al₂O₃, ZrO₂, AlON, HfON, HfSiO, HfSiON, HfZrO, or a combination thereof. The inter-level dielectric layer GD may be formed by a thermal oxidation process of a semiconductor material.

The second conductive line DWL may include a metal-based material, a semiconductor material, or a combination thereof. The second conductive line DWL may include titanium nitride, tungsten, polysilicon, or a combination thereof. For example, the second conductive line DWL may include a titanium nitride/tungsten (TiN/W) stack in which titanium nitride and tungsten are sequentially stacked. The second conductive line DWL may include an N-type work function material or a P-type work function material. The N-type work function material may have a low work function of approximately 4.5 eV or less. The P-type work function material may have a high work function of approximately 4.5 eV or greater. The second conductive line DWL may include a stack of a low work function material and a high work function material.

The data storage element CAP may include a memory element, such as a capacitor. The data storage element CAP may be disposed horizontally in the second direction D2 from the switching element TR. The data storage element CAP may include a first electrode SN extending horizontally from the horizontal layer HL in the second direction D2. The data storage element CAP may further include a second electrode PN over the first electrode SN, and a dielectric layer DE between the first electrode SN and the second electrode PN. The first electrode SN, the dielectric layer DE, and the second electrode PN may be disposed horizontally in the second direction D2. The first electrode SN may include an inner space and a plurality of outer surfaces. The inner space of the first electrode SN may include a plurality of inner surfaces. The outer surfaces of the first electrode SN may include vertical outer surfaces and a plurality of horizontal outer surfaces. The vertical outer surfaces of the first electrode SN may extend vertically in the first direction D1, and the horizontal outer surfaces of the first electrode SN may extend horizontally in the second direction D2 or the third direction D3. The inner space of the first electrode SN may be a three-dimensional space. The dielectric layer DE may conformally cover the inner and outer surfaces of the first electrode SN. The second electrode PN may be disposed in the inner space of the first electrode SN over the dielectric layer DE. Some of the outer surfaces of the first electrode SN may be electrically connected to the second doped region DR of the horizontal layer HL. The second electrode PN of the data storage element CAP may be coupled to a common plate PL.

The data storage element CAP may have a three-dimensional structure. The first electrode SN may have a three-dimensional structure, which may be a horizontal three-dimensional structure which is oriented in the second direction D2. In an example of the three-dimensional structure, the first electrode SN may have a cylindrical shape. The cylindrical shape of the first electrode SN may include cylindrical inner surfaces and cylindrical outer surfaces. Some of the cylindrical outer surfaces of the first electrode SN may be electrically connected to the second doped region DR of the horizontal layer HL. The dielectric layer DE and the second electrode PN may be disposed on the cylindrical inner surfaces of the first electrode SN.

According to another embodiment of the present disclosure, the first electrode SN may have a pillar shape or a pylinder shape. The pylinder shape may refer to a structure in which a pillar shape and a cylindrical shape are merged.

The first electrode SN and the second electrode PN may include a metal, a noble metal, a metal nitride, a conductive metal oxide, a conductive noble metal oxide, a metal carbide, a metal silicide, or a combination thereof. For example, the first electrode SN and the second electrode PN may include titanium (Ti), titanium nitride (TiN), titanium silicon nitride (TiSiN), tantalum (Ta), tantalum nitride (TaN), tungsten (W), tungsten nitride (WN), ruthenium (Ru), ruthenium oxide (RuO₂), iridium (Ir), iridium oxide (IrO₂), platinum (Pt), molybdenum (Mo), molybdenum oxide (MoO), a titanium nitride/titanium silicon nitride (TiSiN) stack, a titanium nitride/tungsten (TiN/W) stack, a tungsten nitride/tungsten (WN/W) stack, or a combination thereof. The second electrode PN may include a combination of a metal-based material and a silicon-based material. For example, the second electrode PN may be a stack of titanium nitride/silicon germanium/tungsten nitride (TiN/SiGe/WN). In the titanium nitride/silicon germanium/tungsten nitride (TiN/SiGe/WN) stack, silicon germanium may be a gap-fill material filling the inside of the first electrode SN, titanium nitride (TiN) may serve as the second electrode PN of the data storage element CAP, and tungsten nitride may be a low-resistance material.

The dielectric layer DE may be referred to as a capacitor dielectric layer or a memory layer. The dielectric layer DE may include silicon oxide, silicon nitride, a high-k material, or a combination thereof. The high-k material may include hafnium oxide (HfO₂), zirconium oxide (ZrO₂), aluminum oxide (Al₂O₃), lanthanum oxide (La₂O₃), titanium oxide (TiO₂), tantalum oxide (Ta₂O₅), niobium oxide (Nb₂O₅) or strontium titanium oxide (SrTiO₃). According to another embodiment of the present disclosure, the dielectric layer DE may be formed of a composite layer including two or more layers of the aforementioned high-k materials.

The dielectric layer DE may be formed of a zirconium-based oxide. The dielectric layer DE may have a stack structure including zirconium oxide (ZrO₂). The dielectric layer DE may include a ZA (ZrO₂/Al₂O₃) stack or a ZAZ (ZrO₂/Al₂O₃/ZrO₂) stack. The ZA stack may have a structure in which aluminum oxide (Al₂O₃) is stacked over zirconium oxide (ZrO₂). The ZAZ stack may have a structure in which zirconium oxide (ZrO₂), aluminum oxide (Al₂O₃), and zirconium oxide (ZrO₂) are sequentially stacked. The ZA stack and the ZAZ stack may be referred to as zirconium oxide (ZrO₂)-based layers. According to another embodiment of the present disclosure, the dielectric layer DE may be formed of hafnium (Hf)-based oxide. The dielectric layer DE may be a stack structure including hafnium oxide (HfO₂). The dielectric layer DE may include an HA (HfO₂/Al₂O₃) stack or an HAH (HfO₂/Al₂O₃/HfO₂) stack. The HA stack may have a structure in which aluminum oxide (Al₂O₃) is stacked over hafnium oxide (HfO₂). The HAH stack may have a structure in which hafnium oxide (HfO₂), aluminum oxide (Al₂O₃), and hafnium oxide (HfO₂) are sequentially stacked. The HA stack and the HAH stack may be referred to as hafnium oxide (HfO₂)-based layers. In the ZA stack, the ZAZ stack, the HA stack, and the HAH stack, aluminum oxide (Al₂O₃) may have a greater band gap energy than zirconium oxide (ZrO₂) and hafnium oxide (HfO₂). Aluminum oxide (Al₂O₃) may have a lower dielectric constant than zirconium oxide (ZrO₂) and hafnium oxide (HfO₂). Therefore, the dielectric layer DE may include a stack of a high-k material and a high band gap material having a greater band gap energy than the high-k material. In addition to aluminum oxide (Al₂O₃), the dielectric layer DE may include silicon oxide (SiO₂) as another high band gap material. By including the high band gap material, the dielectric layer DE may be able to suppress the leakage current. The high band gap material may be thinner than the high-k material. According to another embodiment of the present disclosure, the dielectric layer DE may include a stacked structure in which high-k materials and high band gap materials are alternately stacked. For example, the dielectric layer DE may include a ZAZA (ZrO₂/Al₂O₃/ZrO₂/Al₂O₃) stack, a ZAZAZ (ZrO₂/Al₂O₃/ZrO₂/Al₂O₃/ZrO₂) stack, a HAHA (HfO₂/Al₂O₃/HfO₂/Al₂O₃) stack, a HAHAH (HfO₂/Al₂O₃/HfO₂/Al₂O₃/HfO₂) stack a HZAZH(HfO₂/ZrO₂/Al₂O₃/ZrO₂/HfO₂) stack, a ZHZAZHZ(ZrO₂/HfO₂/ZrO₂/Al₂O₃/ZrO₂/HfO₂/ZrO₂) stack, a HZHZ(HfO₂/ZrO₂/HfO₂/ZrO₂) stack, or AHZAZHA(Al₂O₃/HfO₂/ZrO₂/Al₂O₃/ZrO₂/HfO₂/Al₂O₃) stack. In the above stack structure, the aluminum oxide (Al₂O₃) may be thinner than the zirconium oxide (ZrO₂) and the hafnium oxide (HfO₂).

According to another embodiment of the present disclosure, the dielectric layer DE may include a high-k material and a high band gap material. The dielectric layer DE may have a laminated structure in which a plurality of high-k materials and a plurality of high band gap materials are stacked, or a mixed structure in which the high-k material and the high band gap material are intermixed.

According to another embodiment of the present disclosure, the dielectric layer DE may include a ferroelectric material, an anti-ferroelectric material, or a combination thereof. For example, the dielectric layer DE may include HfZrO.

According to another embodiment of the present disclosure, the dielectric layer DE may include a combination of a high-k material and a ferroelectric material, a combination of a high-k material and an anti-ferroelectric material, a high-k material, or a combination of a ferroelectric material and an anti-ferroelectric material. According to another embodiment of the present disclosure, the dielectric layer DE may include a perovskite dielectric material. The perovskite dielectric material may include SrTiO₃, (Ba,Sr)TiO₃, BaTiO₃, PbTiO₃, PZT, PLZT, or PbTiO₃.

According to another embodiment of the present disclosure, an interface control layer for alleviating leakage current may be further formed between the first electrode SN and the dielectric layer DE. The interface control layer may include titanium oxide (TiO₂), tantalum oxide (Ta₂O₅), niobium oxide (Nb₂O₅), niobium nitride (NbN), or a combination thereof. The interface control layer may also be formed between the second electrode PN and the dielectric layer DE.

The data storage element CAP may include a three-dimensional capacitor. The data storage element CAP may include a Metal-Insulator-Metal (MIM) capacitor. The data storage element CAP may be replaced with another data storage material. For example, the data storage material may be a thyristor, a phase-change material, a Magnetic Tunnel Junction (MTJ), or a variable resistance material.

For example, the memory cell MC may include a thyristor, the first conductive line BL may be a cathode line, and the data storage element CAP may be replaced with an anode line. The horizontal layer HL may include four semiconductor layers that are stacked in the second direction D2. The thyristor may include a first diode and a second diode that are coupled in series. When a forward bias of the same voltage is applied to the thyristor, the thyristor may have a high conductance state in which a large amount of current flows or a low conductance state in which a small amount of current flows or no current flows. The memory cell MC in accordance with the embodiment of the present disclosure may have a ‘1’ state and a ‘0’ state according to the high conductance state and the low conductance state of the thyristor, respectively.

Referring back to FIGS. 1A and 1B, the memory cell MC may further include a first contact node BLC and a second contact node SNC. The first contact node BLC may surround the outer wall of the first conductive line BL. The second contact node SNC may be disposed between the horizontal layer HL and the first electrode SN. The first contact node BLC may include a metal-based material or a semiconductor material. The second contact node SNC may include a metal-based material or a semiconductor material. For example, the first and second contact nodes BLC and SNC may include titanium, titanium nitride, tungsten, or a combination thereof. Also, the first and second contact nodes BLC and SNC may include doped polysilicon. The first doped region SR and the second doped region DR may include impurities diffused from the first contact node BLC and the second contact node SNC, respectively.

FIG. 1D is a schematic cross-sectional view illustrating a memory cell MCi in accordance with another embodiment of the present disclosure. The memory cell MCi of FIG. 1D may be similar to the memory cell MC of FIGS. 1A to 1C. Herein, a detailed description of the constituent elements also appearing in FIGS. 1A to 1C may be omitted.

The memory cell MCi may include a first conductive line BL, a switching element TR, and a data storage element CAP. The switching element TR may include the horizontal layer HL, an inter-level dielectric layer GD, and a second conductive line DWL. The horizontal layer HL may include a first doped region SR, a second doped region DR, and a channel CH. The data storage element CAP may include a first electrode SN, a second electrode PN, and a dielectric layer DE.

The memory cell MCi may further include a first contact node BLC between the first conductive line BL and the horizontal layer HL, and a second contact node SNC between the horizontal layer HL and the data storage element CAP. The first and second contact nodes BLC and SNC may include doped polysilicon. The first doped region SR and the second doped region DR may include impurities diffused from the first contact node BLC and the second contact node SNC, respectively.

The second conductive line DWL may include an upper horizontal line G1 and a lower horizontal line G2. Each of the upper horizontal line G1 and the lower horizontal line G2 may include a first work function electrode G11, a second work function electrode G12, and a third work function electrode G13. The first work function electrode G11, the second work function electrode G12, and the third work function electrode G13 may be horizontally disposed in the second direction D2. The first work function electrode G11, the second work function electrode G12, and the third work function electrode G13 may directly contact each other. The second work function electrode G12 may be disposed adjacent to the first conductive line BL, and the third work function electrode G13 may be disposed adjacent to the data storage element CAP. The horizontal layer HL may have a thickness which is less than the thickness of each of the first, second, and third work function electrodes G11, G12 and G13.

The first work function electrode G11, the second work function electrode G12, and the third work function electrode G13 may be formed of different work function materials. The first work function electrode G11 may have a work function which is greater than the work functions of the second and third work function electrodes G12 and G13. The first work function electrode G11 may include a high work function material. The first work function electrode G11 may have a work function which is greater than the mid-gap work function of silicon. The second and third work function electrodes G12 and G13 may include a low work function material. The second and third work function electrodes G12 and G13 may have a work function which is less than the mid-gap work function of silicon. To be specific, the high work function material may have a work function which is greater than approximately 4.5 eV, and the low work function material may have a work function which is less than approximately 4.5 eV. The first work function electrode G11 may include a metal-based material, and the second and third work function electrodes G12 and G13 may include a semiconductor material.

The second and third work function electrodes G12 and G13 may include polysilicon which is doped with an N-type dopant, i.e., an N-type dopant doped polysilicon. The first work function electrode G11 may include a metal, a metal nitride, or a combination thereof. The first work function electrode G11 may include tungsten, titanium nitride, or a combination thereof. A barrier material may be further formed between the second and third work function electrodes G12 and G13 and the first work function electrode G11.

According to the embodiment of the present disclosure, each of the upper and lower horizontal lines G1 and G2 of the second conductive line DWL may include the second work function electrode G12, the first work function electrode G11, and the third work function electrode G13 that are sequentially and horizontally disposed in the second direction D2. The first work function electrode G11 may include a metal, and the second work function electrode G12 and the third work function electrode G13 may include polysilicon.

Each of the upper and lower horizontal lines G1 and G2 of the second conductive line DWL may have a Poly Si-Metal-Poly Si (PMP) structure in which polysilicon, a metal and polysilicon are horizontally disposed in the second direction D2. In the PMP structure, the first work function electrode G11 may be a metal-based material, and the second and third work function electrodes G12 and G13 may be an N-type dopant doped polysilicon. The N-type dopant may include phosphorus or arsenic.

A first barrier layer G12L may be disposed between the first work function electrode G11 and the second work function electrode G12. A second barrier layer G13L may be disposed between the first work function electrode G11 and the third work function electrode G13. The first and second barrier layers G12L and G13L may include titanium nitride, tantalum nitride, tungsten nitride, or molybdenum nitride. The second barrier layer G13L may cover the upper surface, the lower surface, and one side surface of the first work function electrode G11.

The first work function electrode G11 may have a volume greater than the second and third work function electrodes G12 and G13, and accordingly, the second conductive line DWL may have a low resistance. The first work function electrodes G11 of the upper and lower horizontal lines G1 and G2 may vertically overlap with each other in the first direction D1 with the horizontal layer HL interposed therebetween. The second and third work function electrodes G12 and G13 of the upper and lower horizontal lines G1 and G2 may also vertically overlap with each other in the first direction D1 with the horizontal layer HL interposed therebetween. The overlapping portion of the first work function electrode G11 and the horizontal layer HL may be greater than the overlapping portion of the second and third work function electrodes G12 and G13 and the horizontal layer HL. The first work function electrode G11 may extend in the third direction D3, and the second and third work function electrodes G12 and G13 may have an independent structure that overlaps with the horizontal layer HL. For example, the first work function electrode G11 may include a channel overlapping portion WLP and a channel non-overlapping portion NOL, and the second and third work function electrodes G12 and G13 may be part of the channel overlapping portion WLP. The second and third work function electrodes G12 and G13 and the first work function electrode G11 may directly contact each other.

As described above, each of the upper and lower horizontal lines G1 and G2 may have a triple-work function electrode structure including the first, second and third work function electrodes G11, G12 and G13. The second conductive line DWL may have a pair of first work function electrodes G11, a pair of second work function electrodes G12, and a pair of third work function electrodes G13 extending in the third direction D3 across the horizontal layer HL with the horizontal layer HL interposed therebetween. The first work function electrodes G11, the second work function electrodes G12, and the third work function electrodes G13 may vertically overlap with the channel CH.

Each of the second conductive lines DWL may include a channel overlapping portion WLP and a channel non-overlapping portion NOL as illustrated in FIG. 1C. The channel overlapping portions WLP may have a cross shape or a rhombus shape. The channel overlapping portions WLP may fully overlap with the channel CH. The second conductive line DWL extending in the third direction D3 may have notch-shaped sidewalls due to the channel overlapping portions WLP and the channel non-overlapping portions NOL. From the perspective of a top view, the notch-shaped sidewalls may be provided by protruding portions that are formed by the channel overlapping portions WLP, and recessed portions that are formed by the channel non-overlapping portions NOL. The channel overlapping portion WLP may include first work function electrodes G11, second work function electrodes G12, and third work function electrodes G13. The first work function electrodes G11, the second work function electrodes G12, and the third work function electrodes G13 may vertically overlap with the channel CH.

In the second direction D2, the first work function electrode G11 having a high work function may be disposed at the center of the second conductive line DWL, and the second and third work function electrodes G12 and G13 having a low work function may be disposed on both end portions of the second conductive line DWL, thereby alleviating leakage current, such as Gate-Induced Drain Leakage (GIDL).

The threshold voltage of the switching element TR may be increased by disposing the first work function electrode G11 having a high work function at the center of the second conductive line DWL. Since the second work function electrode G12 of the second conductive line DWL has a low work function, a low electric field may be formed between the first conductive line BL and the second conductive line DWL. Since the third work function electrode G13 of the second conductive line DWL has a low work function, a low electric field may be formed between the data storage element CAP and the second conductive line DWL.

As described above, the memory cell MCi may include a second conductive line DWL having a triple work function electrode structure. Each of the upper and lower horizontal lines G1 and G2 of the second conductive line DWL may include the first work function electrode G11, the second work function electrode G12, and the third work function electrode G13. The first work function electrode G11 may overlap with the channel CH. The second work function electrode G12 may be disposed adjacent to the first conductive line BL and the first doped region SR. The third work function electrode G13 may be disposed adjacent to the data storage element CAP and the second doped region DR. Due to the low work function of the second work function electrode G12, a low electric field may be formed between the second conductive line DWL and the first conductive line BL, which may alleviate the leakage current. Due to the low work function of the third work function electrode G13, a low electric field may be formed between the second conductive line DWL and the data storage element CAP, which may alleviate the leakage current. Due to the high work function of the first work function electrode G11, the threshold voltage of the switching element TR may be increased. Also, due to the high work function of the first work function electrode G11, the height of the memory cell MCi may be decreased, which is advantageous in terms of integration.

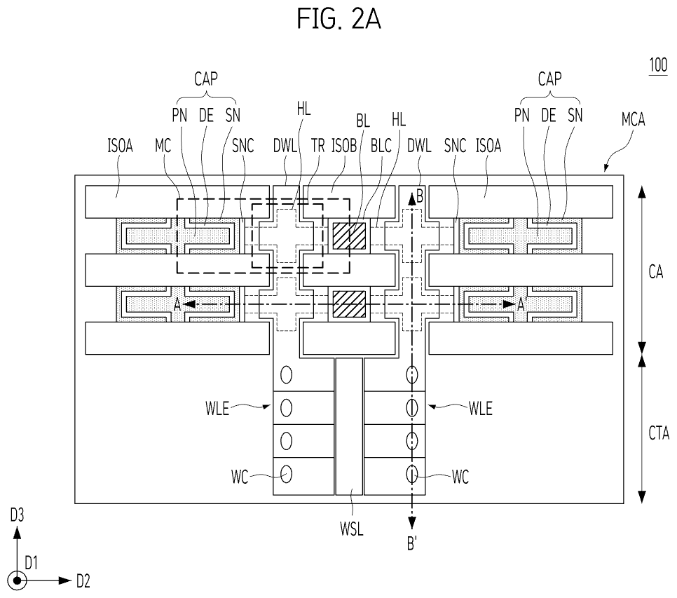

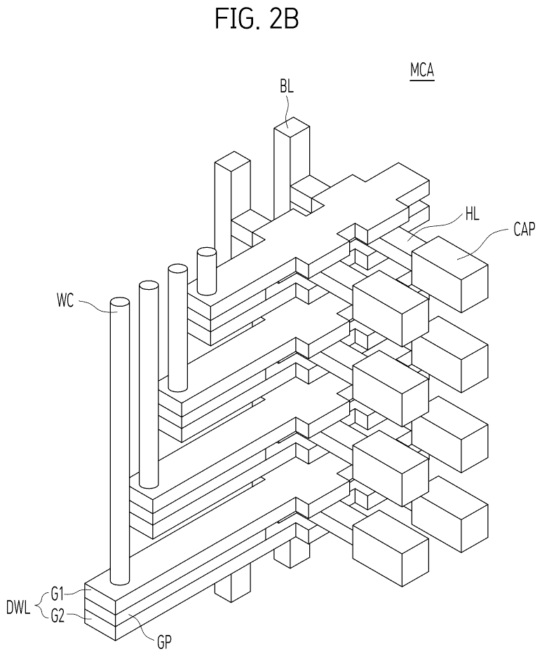

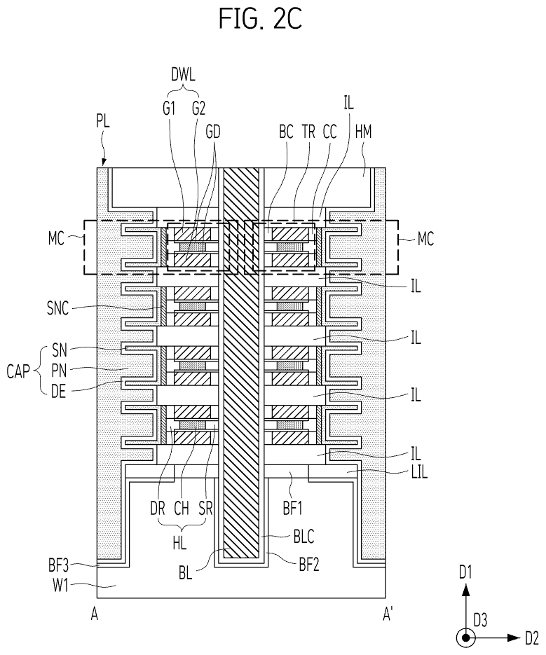

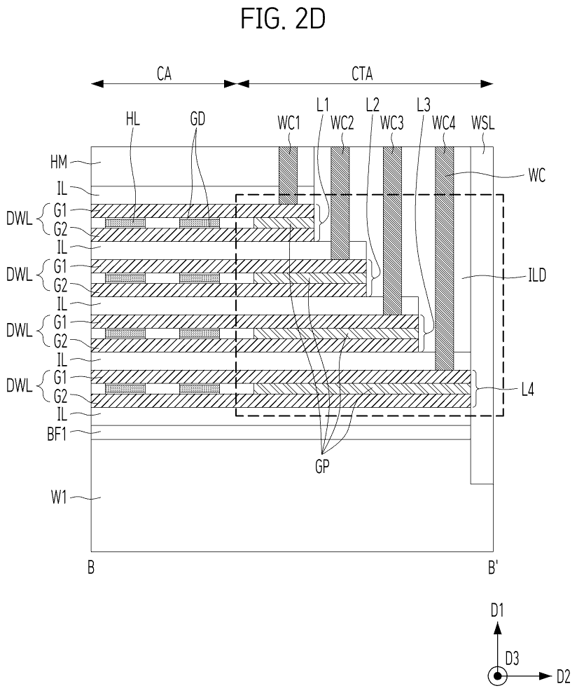

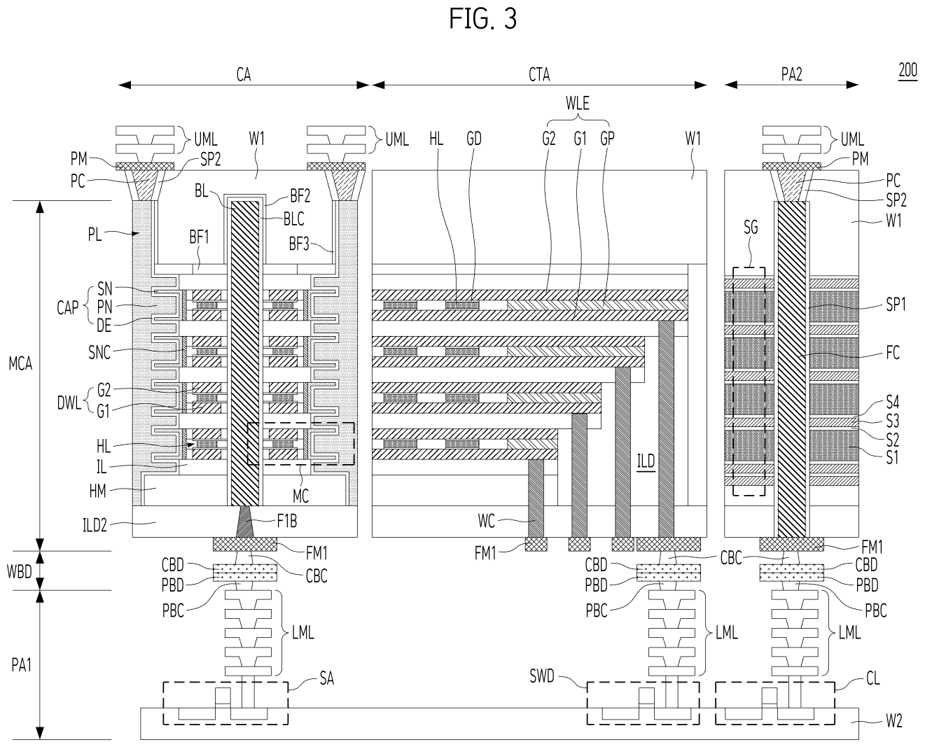

FIG. 2A is a schematic plan view illustrating a semiconductor device 100 in accordance with an embodiment of the present disclosure. FIG. 2B is a schematic perspective view illustrating a memory cell array MCA of FIG. 2A. FIG. 2C is a schematic cross-sectional view taken along a line A-A′ shown in FIG. 2A. FIG. 2D is a schematic cross-sectional view taken along a line B-B′ shown in FIG. 2A.

Referring to FIGS. 2A, 2B, 2C, and 2D, the semiconductor device 100 may include a memory cell array MCA. The memory cell array MCA may include a plurality of memory cells MC. Each of the memory cells MC may be described with reference to FIGS. 1A to 1C. Each memory cell MC may include a first conductive line BL, a switching element TR, and a data storage element CAP. According to another embodiment of the present disclosure, each of the memory cells MC may be the same as the memory cell MCi of FIG. 1D. The switching element TR may include a second conductive line DWL and a horizontal layer HL.

The memory cell array MCA may include a first region CA and a second region CTA. The first region CA may be a region where memory cells MC are formed, and the second region CTA may be a region where cell contact plugs WC coupled to the second conductive lines DWL of the memory cells MC are formed.

The memory cell array MCA may include a three-dimensional array of memory cells MC. The three-dimensional array of the memory cells MC may include a column array of memory cells MC and a row array of memory cells MC. For example, the memory cell array MCA may include a plurality of column arrays. The column array of the memory cells MC may include a plurality of memory cells MC that are stacked in the first direction D1. The row array of the memory cells MC may include a plurality of memory cells MC that are horizontally disposed in the second direction D2 and the third direction D3.

The memory cell array MCA may include a plurality of first mirror-type sub-cell arrays and a plurality of second mirror-type sub-cell arrays. The first mirror-type sub-cell array may include a mirror-type structure in which two memory cells MC adjacent in the second direction D2 share a first conductive line BL. The second mirror-type sub-cell array may include a mirror-type structure in which two memory cells MC share the second electrode PN of the data storage element CAP in the second direction D2.

Iner-cell dielectric layers IL may be disposed between the memory cells MC that are stacked in the first direction D1. Cell isolation layers ISOA and ISOB may be disposed between the memory cells MC that are adjacent to each other in the third direction D3. The cell isolation layers ISOA and ISOB may include silicon oxide, silicon carbon oxide (SiCO), silicon nitride, or a combination thereof. The cell isolation layers may include first cell isolation layers ISOA and second cell isolation layers ISOB. The first cell isolation layers ISOA and the second cell isolation layers ISOB may extend vertically in the first direction D1. The first cell isolation layers ISOA and the second cell isolation layers ISOB may be alternately and repeatedly disposed in the second direction D2. The first cell isolation layers ISOA may be disposed between the data storage elements CAP in the third direction D3. The second cell isolation layers ISOB may be disposed between the first conductive lines BL in the third direction D3. The second conductive lines DWL may be disposed between the first cell isolation layers ISOA and the second cell isolation layers ISOB in the second direction D2.

The memory cell array MCA may be disposed over a first substrate W1.

The memory cell array MCA may include a plurality of first conductive lines BL extending vertically in the first direction D1. The memory cell array MCA may include a plurality of second conductive lines DWL that are vertically stacked in the first direction D1. The memory cell array MCA may include a plurality of horizontal layers HL that are vertically stacked in the first direction D1. The memory cell array MCA may include a plurality of data storage elements CAP that are vertically stacked in the first direction D1. The memory cell array MCA may include an alternating stack of the second conductive lines DWL and the inter-cell dielectric layers IL that are stacked in the first direction D1.

Each of the second conductive lines DWL may have a double structure. For example, the second conductive line DWL may include an upper horizontal line G1 and a lower horizontal line G2 that are facing each other with a horizontal layer HL interposed between them. An inter-level dielectric layer GD may be formed on an upper surface and a lower surface of the horizontal layer HL. The upper horizontal line G1 may be disposed over the horizontal layer HL, and the lower horizontal line G2 may be disposed below the horizontal layer HL. The second conductive line DWL may include a pair of the upper horizontal line G1 and the lower horizontal line G2. Each of the second conductive lines DWL may include a channel overlapping portion WLP as illustrated in FIG. 1C. The channel overlapping portion WLP may have a cross shape or a rhombus shape. The channel overlapping portion WLP may fully overlap with the channel CH. The second conductive line DWL extending in the third direction D3 may include a plurality of channel overlapping portions WLP. The second conductive line DWL may have a notch-shaped sidewall due to the channel overlapping portions WLP.

A plurality of first passivation layers BF1 may be disposed between the lowermost second conductive line DWL among the second conductive lines DWL and the first substrate W1. A second passivation layer BF2 may be disposed between the first conductive line BL and the first substrate W1. Third passivation layers BF3 may be disposed between the data storage element CAP and the first substrate W1. The first to third passivation layers BF1, BF2 and BF3 may include a dielectric material. The first to third passivation layers BF1, BF2 and BF3 may include silicon oxide. The first to third passivation layers BF1, BF2 and BF3 may electrically disconnect the first conductive line BL, the second conductive lines DWL and the data storage elements CAP from the first substrate W1.

The first conductive line BL may extend vertically in the first direction D1 from the upper portion of the first substrate W1. The horizontal layers HL may extend in the second direction D2 intersecting with the first direction D1. The second conductive lines DWL may extend in the third direction D3 intersecting with the first direction D1 and the second direction D2.

The horizontal layer HL may include a channel CH, a first doped region SR between the channel CH and the first conductive line BL, and a second doped region DR between the channel CH and the data storage element CAP. From the perspective of a top view, the horizontal layers HL may have a cross-shape or a rhombus shape. According to another embodiment of the present disclosure, the side surfaces of the horizontal layer HL may have a bent shape or a rounded shape. As illustrated in FIGS. 1B and 2C, the horizontal layer HL may include a channel CH.

A first capping layer BC may be disposed between the second conductive line DWL and the first conductive line BL. A second capping layer CC may be disposed between the second conductive line DWL and the first electrode SN of the data storage element CAP. The first capping layer BC may be disposed between the upper conductive line G1 and the first conductive line BL, and also, the first capping layer BC may be disposed between the lower conductive line G2 and the first conductive line BL. The second capping layer CC may be disposed between the upper conductive line G1 and the first electrode SN of the data storage element CAP, and also, the second capping layer CC may be disposed between the lower conductive line G2 and the first electrode SN of the data storage element CAP.

The first and second capping layers BC and CC may include a dielectric material. The first and second capping layers BC and CC may include silicon oxide, silicon nitride, silicon carbon oxide, an air gap, or a combination thereof. The first and second capping layers BC may include a stack of silicon oxide and silicon nitride.

The horizontal layers HL of the switching elements TR horizontally disposed in the third direction D3 may share one second conductive line DWL. The horizontal layers HL of the switching elements TR horizontally disposed in the third direction D3 may be coupled to different first conductive lines BL. The switching elements TR stacked in the first direction D1 may share one first conductive line BL. The switching elements TR horizontally disposed in the third direction D3 may share one second conductive line DWL.

The first cell isolation layers ISOA may be disposed between the first electrodes SN of the data storage elements CAP in the third direction D3. The first electrodes SN may be separated from each other by the first cell isolation layers ISOA. The second electrodes PN of the data storage elements CAP may be coupled to a common plate PL. The second electrodes PN of the data storage elements CAP may be merged to become a common plate PL.

The first cell isolation layers ISOA may be disposed between the data storage elements CAP in the third direction D3. The second cell isolation layers ISOB may be disposed between the vertical conductive lines BL in the third direction D3. The second conductive line DWL may be disposed between the first cell isolation layers ISOA and the second cell isolation layers ISOB in the second direction D2.

The first substrate W1 may be a material appropriate for semiconductor processing. The first substrate W1 may include one or more among conductive materials, dielectric materials, and semiconductive materials. Diverse materials may be formed over the first substrate W1. The first substrate W1 may include a semiconductor substrate. The first substrate W1 may be formed of a material containing silicon. The first substrate W1 may include silicon, monocrystalline silicon, polysilicon, amorphous silicon, silicon germanium, monocrystalline silicon germanium, polycrystalline silicon germanium, carbon-doped silicon, a combination thereof, or a multi-layer thereof. The first substrate W1 may include other semiconductor materials, such as germanium. The first substrate W1 may include a III-V group semiconductor substrate, for example, a compound semiconductor substrate, such as gallium arsenide (GaAs). The first substrate W1 may include an Silicon-On-Insulator (SOI) substrate.

According to another embodiment of the present disclosure, the memory cell array MCA may include a Dynamic Random Access Memory (DRAM), an embedded DRAM, a NAND, a ferroelectric Random Access Memory (FeRAM), a Spin Transfer Torque Random Access Memory (STT-RAM), a Phase-Change RAM (PCRAM), or a Resistive RAM (ReRAM).

Referring to FIG. 2D, the second conductive lines DWL may be disposed in the first region CA, and portions of the second conductive lines DWL may extend to the second region CTA. The portions of the second conductive lines DWL disposed in the second region CTA may be referred to as a pad portion WLE, an edge portion, or a pad stack. The stack of the second conductive lines DWL may include a first stack and a second stack. The first stack may be a portion formed in the first region CA, and the second stack may be a portion formed in the second region CTA. One side of the pad portion WLE of FIG. 2A may be covered by an inter-layer dielectric layer ILD.

The pad portion WLE of the second conductive lines DWL may include a plurality of levels L1, L2, L3 and L4. In the pad portion WLE, each of the horizontal conductive lines DWL of the levels L1 to L4 may include a pair of the upper horizontal line G1 and the lower horizontal line G2. In the pad portion WLE, the levels L1 to L4 may further include pads PD. Pads GP may be disposed between the upper horizontal line G1 and the lower horizontal line G2. Each of the pads GP may be electrically connected to the upper horizontal line G1 and the lower horizontal line G2.

The lateral lengths of the pads GP in the third direction D3 may be different from each other. For example, the lateral lengths of the pads GP may be gradually decreased as it goes from the fourth level L4 to the first level L1 in the first direction D1.

The pads GP and the horizontal layers HL may be spaced apart from each other. The pads GP may not be disposed in the first region CA.

The pads GP, the upper horizontal lines G1 and the lower horizontal lines G2 may include the same material. The pads GP, the upper horizontal lines G1 and the lower horizontal lines G2 may include a metal-based material. For example, the pads GP, the upper horizontal lines G1 and the lower horizontal lines G2 may include titanium nitride, tungsten or a combination thereof.

The second region CTA may include contact plugs WC1, WC2, WC3 and WC4 respectively coupled to the second conductive lines DWL of the pad portion WLE.

The second region CTA may include the pad portion WLE in which the first conductive lines DWL and the inter-cell dielectric layers IL are alternately stacked. The second region CTA may include an array of contact plugs WC1, WC2, WC3 and WC4 disposed in the pad portion WLE, laterally spaced apart from each other in the second horizontal direction (i.e., the third direction D3), and having different heights. The top surfaces of the contact plugs WC1, WC2, WC3 and WC4 may be disposed on the same horizontal plane, and the bottom portions of the contact plugs WC1, WC2, WC3 and WC4 may be adjoined to the second conductive lines DWL, respectively.

The first contact plug WC1 may be electrically connected to the second conductive line DWL of the first level L1. The first contact plug WC1 may be electrically connected to the upper horizontal line G1 of the first level L1. The second contact plug WC2 may be electrically connected to the second conductive line DWL of the second level L2. The second contact plug WC2 may be electrically connected to the upper horizontal line G1 of the second level L2 by passing through the cell insulation layer IL. The third contact plug WC3 may be electrically connected to the second conductive line DWL of the third level L3. The third contact plug WC3 may be electrically connected to the upper horizontal line G1 of the third level L3 by passing through the cell insulation layer IL. The fourth contact plug WC4 may be electrically connected to the second conductive line DWL of the fourth level L4. The fourth contact plug WC4 may be electrically connected to the upper horizontal line G1 of the fourth level L4 by passing through the cell insulation layer IL.

The vertical height of the fourth contact plug WC4 may be greater than the vertical height of the third contact plug WC3, and the vertical height of the third contact plug WC3 may be greater than the vertical height of the second contact plug WC2. The vertical height of the second contact plug WC2 may be greater than the vertical height of the first contact plug WC1. Here, the vertical height may refer to the height in the first direction D1.

As described above, the pad portion WLE of the second conductive lines DWL may have a stair structure.

FIG. 3 is a schematic cross-sectional view illustrating a semiconductor device 200 in accordance with another embodiment of the present disclosure.

Referring to FIG. 3, the semiconductor device 200 may include a memory cell array MCA, a peripheral circuit region PA1, and a dummy region PA2. The memory cell array MCA may be disposed at a higher level than the peripheral circuit region PA1. The dummy region PA2 may be horizontally spaced apart from the memory cell array MCA. For the detailed description of the memory cell array MCA of FIG. 3, FIGS. 2A to 2D may be referred to.

The memory cell array MCA and the dummy region PA2 may be formed on a first substrate W1. The peripheral circuit region PA1 may be formed on a second substrate W2. The memory cell array MCA may include a three-dimensional array of memory cells MC, which may include a column array of memory cells MC and a row array of memory cells MC. For the detailed description of the memory cells MC, FIGS. 1A to 1C may be referred to. Each memory cell MC may include a first conductive line BL, a switching element TR, and a data storage element CAP. According to another embodiment of the present disclosure, each memory cell MC may be identical to the memory cell MCi of FIG. 1D. The memory cell array MCA may include a plurality of first conductive lines BL extending vertically in the first direction D1. The memory cell array MCA may include a plurality of second conductive lines DWL that are vertically stacked in the first direction D1. The memory cell array MCA may include a plurality of horizontal layers HL that are vertically stacked in the first direction D1. The memory cell array MCA may include a plurality of data storage elements CAP that are vertically stacked in the first direction D1. The memory cell array MCA may include an alternating stack of the second conductive lines DWL and the inter-cell dielectric layers IL that are stacked in the first direction D1.

The memory cell array MCA may include a first region CA and a second region CTA. The first region CA may have memory cells MC formed therein, and the second region CTA may have cell contact plugs WC formed therein. In the second region CTA, a pad portion WLE of the second conductive lines DWL may be disposed, and the second conductive lines DWL of the pad portion WLE may be coupled to the cell contact plugs WC. The second conductive lines DWL of the pad portion WLE may have a stair structure. An inter-layer dielectric layer ILD formed over the pad portion WLE, and the cell contact plugs WC passing through the inter-layer dielectric layer ILD.

The peripheral circuit region PA1 may include a semiconductor substrate, a metal interconnection structure, an insulation structure, a conductive structure, another memory or a peripheral circuit portion.

Referring to FIG. 3, the peripheral circuit region PA1 may be disposed at a lower level than the memory cell array MCA. This may be referred to as a Cell-over-PERI (COP) structure. The first substrate W1 is flipped to bond the memory cell array MCA and the peripheral circuit region PA1.

The peripheral circuit region PA1 may be coupled to the memory cell array MCA. The peripheral circuit region PA1 may include one or more control circuits for driving the memory cell array MCA. The one or more control circuits of the peripheral circuit portion may include an N-channel transistor, a P-channel transistor, a CMOS circuit, or a combination thereof. The one or more control circuits of the peripheral circuit portion may include an address decoder circuit, a read circuit, a write circuit, and the like. The one or more control circuits of the peripheral circuit portion may include a planar channel transistor, a recess channel transistor, a buried gate transistor, a fin channel transistor (FinFET), and the like.

For example, the peripheral circuit region PA1 may include a plurality of control circuits that are formed over the second substrate W2. For example, the peripheral circuit region PA1 may include sub-word line drivers SWD and a sense amplifier SA. The second conductive lines DWL of the memory cell array MCA may be coupled to the sub-word line drivers SWD. The first conductive lines BL of the memory cell array MCA may be coupled to the sense amplifier SA. The peripheral circuit region PA1 may further include a peripheral control circuit CL.

The peripheral circuit region PA1 and the memory cell array MCA may be coupled to each other by a bonding structure WBD. The peripheral circuit region PA1 and the dummy region PA2 may be coupled to each other by a bonding structure WBD and a first multi-layer level interconnection LML. The bonding structure WBD may include a plurality of bonding pads CBD and PBD. The peripheral circuit region PA1 and the memory cell array MCA may be coupled to each other by the bonding structure WBD and the first multi-layer level interconnection LML.

The bonding pads CBD and PBD may include first bonding pads CBD and second bonding pads PBD. The first bonding pads CBD and the second bonding pads PBD may be coupled to each other by wafer bonding. First bonding contact plugs CBC may be coupled to the first bonding pads CBD. Second bonding contact plugs PBC may be coupled to the second bonding pads PBD.

The first conductive lines BL of the memory cell array MCA may be coupled to the first bonding pads CBD and the first bonding contact plugs CBC through the front level interconnection FM1. A front level plug F1B disposed between the first conductive lines BL and the front level interconnection FM1.

The cell contact plugs WC of the memory cell array MCA may be coupled to the first bonding pads CBD and the first bonding contact plugs CBC through the front level interconnection FM1.

The common plate PL of the data storage elements CAP of the memory cell array MCA may be coupled to a second multi-layer level interconnection UML through a nano-through silicon via PC and a post-level interconnection PM. The nano-through silicon vias PC may penetrate the back side of the first substrate W1. Nano level spacers SP2 may be formed on the sidewalls of the nano-through silicon vias PC. The nano level spacers SP2 may be disposed between the nano-through silicon vias PC and the first substrate W1. The nano-through silicon vias PC may be coupled to the common plate line PL passing through the first substrate W1 from the back side of the first substrate W1. The nano-through silicon vias PC are embedded in the first substrate W1, and sidewalls of the nano-through silicon vias PC are fully surrounded by and isolated from the first substrate W1 by the nano level spacers SP2.

The dummy region PA2 may be disposed at a higher level than the peripheral circuit region PA1. The dummy region PA2 may include a dummy stack SG, a stack level plug FC passing through the dummy stack SG, and a stack level spacer SP1 formed on the sidewall of the stack level plug FC. The stack level spacer SP1 may include a dielectric material. The dummy stack SG may include silicon layers S1 and S3 and silicon germanium layers S2 and S4.

The stack level spacers SP1 may be disposed between the stack level plugs FC and the dummy stack SG. A stack of the silicon layers S1 and S3 and the silicon germanium layers S2 and S4 may be disposed around the stack level plugs FC and the stack level spacers SP1.

The vertical height of the stack level plug FC may be greater than the vertical height of the nano-through silicon via PC.

The second multi-layer level interconnection UML and post-level interconnection PM may be coupled to an upper portion of the stack level plug FC. The front level interconnection FM1 may be coupled to a lower portion of the stack level plug FC. The stack level plug FC may be coupled to the second multi-layer level interconnection UML through the nano-through silicon via PC and the post-level interconnection PM. The front level interconnection FM1 may be coupled to the first bonding contact plugs CBC and the first bonding pads CBD. The peripheral control circuit CL may be coupled to the second bonding contact plugs PBC and the second bonding pads PBD through the first multi-layer level interconnection LML. The nano-through silicon vias PC are embedded in the first substrate W1, and sidewalls of the nano-through silicon vias PC are fully surrounded by and isolated from the first substrate W1 by the nano level spacers SP2.

The sub-word line drivers SWD and the sense amplifier SA may be coupled to the second bonding contact plugs PBC and the second bonding pads PBD through the first multi-layer level interconnection LML.

The nano-through silicon via PC, the post-level interconnection PM and the second multi-layer level interconnection UML may be the back-side interconnection structure. The peripheral control circuit CL may be electrically coupled to the back-side interconnection structure through a vertical path of the first multi-layer level interconnection LML, the bonding structure WBD and the stack level plug FC.

The semiconductor device 200 of FIG. 3 may include a COP structure, and the memory cell array MCA and the dummy region PA2 may be disposed at a higher level than the peripheral circuit region PA1. As described above, since the spacers SP1 and SP2 are formed on the sidewalls of the stack level plug FC and the nano-through silicon via PC, it is possible to prevent a short circuit between the stack level plug FC and the nano-through silicon via PC and the first substrate W1. Also, it is possible to prevent a short circuit between the stack level plug FC and the nano-through silicon via PC.

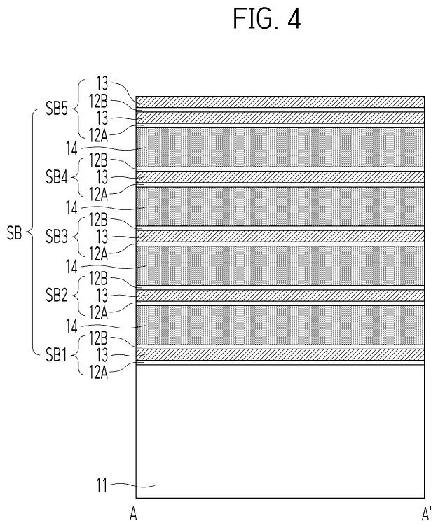

FIGS. 4 to 22 illustrate a method for fabricating a semiconductor device in accordance with embodiments of the present disclosure.

Referring to FIG. 4, a stack body SB may be formed over a first substrate 11. The first substrate 11 may include a semiconductor substrate. The stack body SB may have a plurality of sub-stacks that are stacked alternately. Each of the sub-stacks may include a first layer 12A, a second layer 13, a third layer 12B, and a preliminary horizontal layer 14 that are stacked in the mentioned order. The first layer 12A and the third layer and 12B may be formed of the same material and may include silicon germanium. The second layers 13 may include monocrystalline silicon. The preliminary horizontal layers 14 may include monocrystalline silicon. The second layers 13 and the preliminary horizontal layers 14 may be of the same material. The first layer 12A, the second layer 13, the third layer 12B, and the preliminary horizontal layer 14 may be formed by an epitaxial growth process. The first layer 12A may be thinner than the second layer 13, and the preliminary horizontal layer 14 may be thicker than the second layer 13.

The stack body SB may include a plurality of preliminary horizontal layers 14, a first sacrificial layer stack SB1, a second sacrificial layer stack SB2, a third sacrificial layer stack SB3, a fourth sacrificial layer stack SB4, and a fifth sacrificial layer stack SB5. The stack body SB may include the first sacrificial layer stack SB1, the preliminary horizontal layer 14, the second sacrificial layer stack SB2, the preliminary horizontal layer 14, the third sacrificial layer stack SB3, the preliminary horizontal layer 14, the fourth sacrificial layer stack SB4, the preliminary horizontal layer 14, and the fifth sacrificial layer stack SB5 that are stacked in the mentioned order. The uppermost layer of the stack body SB may be the second layer 13. Each of the first to fifth sacrificial layer stacks SB1 to SB5 may be a triple-layer stack of the first layer 12A, the second layer 13, and the third layer 12B. For example, when the first layer 12A and the third layer 12B include a silicon germanium layer and the second layer 13 includes a monocrystalline silicon layer, the first to fifth sacrificial layer stacks SB1 to SB5 may include a stack of a first silicon germanium layer, a monocrystalline silicon layer, and a second silicon germanium layer (SiGe/Si/SiGe). The fifth sacrificial layer stack SB5 may be a quadruple layer of the first layer 12A/the second layer 13/the third layer 12B/the second layer 13. The fifth sacrificial layer stack SB5 may be used as a hard mask.

The second layer 13 may include a first monocrystalline silicon layer, and the preliminary horizontal layer 14 may include a second monocrystalline silicon layer. Accordingly, the stack body SB may have the first sacrificial layer stack SB1 which is disposed below the second monocrystalline silicon layer, and the second sacrificial layer stack SB2 which is disposed over the second monocrystalline silicon layer. Each of the first and second sacrificial layer stacks SB1 and SB2 may include a stack of a first silicon germanium layer, a first monocrystalline silicon layer, and a second silicon germanium layer. The second monocrystalline silicon layer may be thicker than the first monocrystalline silicon layer.

As described above with reference to the embodiments of the present disclosure, when the memory cells are stacked, the first sacrificial layer stack SB1, the preliminary horizontal layer 14, the second sacrificial layer stack SB2, the preliminary horizontal layer 14, the third sacrificial layer stack SB3, the preliminary horizontal layer 14, the fourth sacrificial layer stack SB4, the preliminary horizontal layer 14, and the fifth sacrificial layer stack SB5 may be alternately stacked several times.

According to another embodiment of the present disclosure, the preliminary horizontal layer 14 may include amorphous silicon or polysilicon.

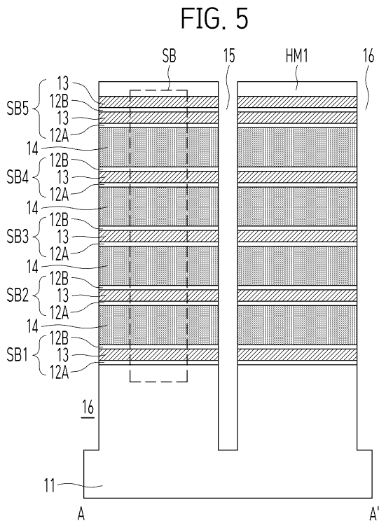

Referring to FIG. 5, portions of the stack body SB may be etched. As a result, a plurality of vertical openings 15 and 16 may be formed in the stack body SB. The vertical openings 15 and 16 may include first vertical openings 15 and second vertical openings 16. From the perspective of a top view, the first vertical openings 15 and the second vertical openings 16 may be hole-shaped vertical openings. According to another embodiment of the present disclosure, the first vertical openings 15 and the second vertical openings 16 may be line-shaped vertical openings.

As described above, a hard mask layer pattern HM1 may be formed to form the vertical openings 15 and 16, and the hard mask layer pattern HM1 may be formed by using a double patterning process.

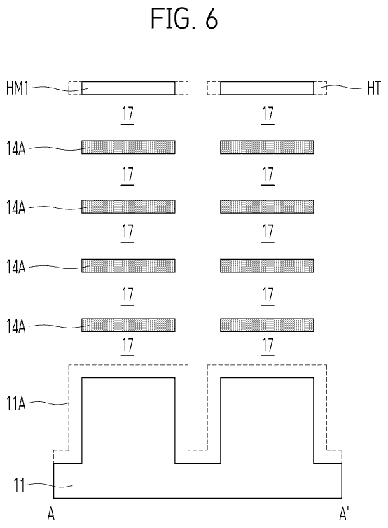

Referring to FIG. 6, a portion HT of the hard mask layer pattern HM1 may be trimmed.

Subsequently, the first layers 12A and the third layers 12B of FIG. 5 may be selectively removed through the vertical openings 15 and 16.

To selectively remove the first layers 12A and the third layers 12B, the difference between the etching selectivities of the second layers 13 and the preliminary horizontal layers 14 and the etching selectivities of the first layers 12A and the third layers 12B may be used. The first layers 12A and the third layers 12B may be removed by a wet etching process or a dry etching process. For example, when the first layers 12A and the third layers 12B include a silicon germanium layer and the second layers 13 and the preliminary horizontal layers 14 include a silicon layer, the silicon germanium layers may be etched by using an etchant or etching gas having a selectivity with respect to the silicon layers.

Subsequently, the second layers 13 may be removed. The second layers 13 may be removed by a wet etching process or a dry etching process. According to an embodiment of the present disclosure, the preliminary horizontal layers 14 may be partially removed while removing the second layers 13. As a result, the second layers 13 may be removed, and the preliminary horizontal layers 14 may become thin as indicated by a reference numeral ‘14A’. The recess process for forming the thin preliminary horizontal layers 14A, i.e., the preliminary horizontal layer patterns 14A, may be referred to as a thinning process or a trimming process of the preliminary horizontal layers 14. The preliminary horizontal layer patterns 14A may be referred to as a thin-body active layer. The preliminary horizontal layer patterns 14A may include a monocrystalline silicon layer. While the preliminary horizontal layer patterns 14A are formed, the surface of the first substrate 11 may be recessed to a predetermined depth. The recess process for forming the preliminary horizontal layer patterns 14A may use Hot SC-1 (HSC1). HSC1 may include a solution in which ammonium hydroxide (NH₄OH), hydrogen peroxide (H₂O₂), and water (H₂O) are mixed in a ratio of approximately 1:4:20. The second layers 13 and the preliminary horizontal layers 14 may be selectively etched by using the HSC1.

As a result of the recess process described above, the preliminary horizontal layer patterns 14A and wide recesses 17 may be formed. Each of the upper surface and the lower surface of the preliminary horizontal layer patterns 14A may include a flat surface.

From the perspective of a top view, the preliminary horizontal layer patterns 14A may have a cross shape. The side surfaces of the preliminary horizontal layer patterns 14A may have a bent shape or a rounded shape.

After the preliminary horizontal layer patterns 14A are formed, the vertical openings 15 and 16 may be expanded.

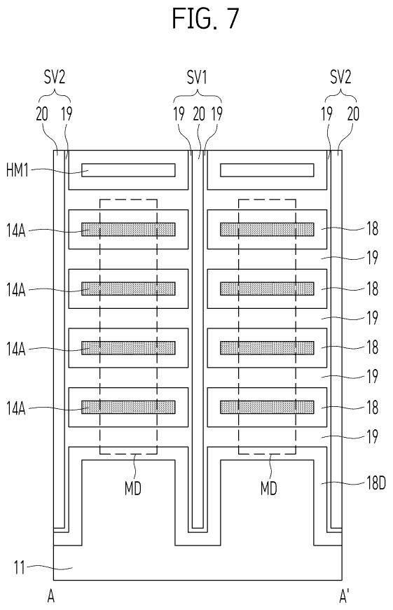

Referring to FIG. 7, first dielectric layers 18 may be formed to fully cover the preliminary horizontal layer patterns 14A. The first dielectric layers 18 may include silicon nitride.

While the first dielectric layers 18 are formed, a dummy dielectric layer 18D may be formed on the surface of the first substrate 11.

Subsequently, a second dielectric layer 19 may be formed over the first dielectric layers 18. The second dielectric layer 19 may fill between the vertically neighboring first dielectric layers 18. The second dielectric layer 19 may include silicon oxide. Portions of the second dielectric layer 19 may be conformally formed on the surfaces of the vertical openings 15 and 16. Each of the wide recesses 17 of FIG. 6 may be filled with the first dielectric layer 18 and the second dielectric layer 19.

The first dielectric layers 18 may surround the preliminary horizontal layer pattern 14A, and the second dielectric layers 19 may surround the first dielectric layers 18.

Subsequently, sacrificial pillars 20 may be formed over the second dielectric layers 19 which are disposed in the vertical openings 15 and 16. The sacrificial pillars 20 may include amorphous carbon. According to another embodiment of the present disclosure, a pillar capping layer may be further formed over the sacrificial pillars 20. The pillar capping layer may include a metal-based material. The pillar capping layer may include titanium nitride.

The second dielectric layers 19 and the sacrificial pillars 20 may form first and second sacrificial pillar structures SV1 and SV2 that fill the vertical openings 15 and 16. The first sacrificial pillar structure SV1 may fill the first vertical openings 15, and the second sacrificial pillar structure SV2 may fill the second vertical openings 16. The sacrificial pillars 20 may not be formed between the first dielectric layers 18 that are stacked vertically. According to another embodiment of the present disclosure, each of the first and second sacrificial pillar structures SV1 and SV2 may include a dielectric material, a carbon-containing material, a metal-based material, or a combination thereof. Each of the first and second sacrificial pillar structures SV1 and SV2 may include silicon oxide, silicon nitride, titanium nitride, amorphous carbon, or a combination thereof.

As the preliminary horizontal layer patterns 14A, the first dielectric layers 18, and the second dielectric layers 19 are formed, and a cell mold structure MD may be formed. The cell mold structure MD may include a plurality of cell molds. Each cell mold may include a plurality of mold layers. For example, each cell mold may include a first mold layer, a second mold layer, a third mold layer, a fourth mold layer, and a fifth mold layer that are sequentially stacked. The first mold layer and the fifth mold layer may correspond to the second dielectric layers 19. The second mold layer and the fourth mold layer may correspond to the first dielectric layers 18. The third mold layer may correspond to the preliminary horizontal layer pattern 14A. Each cell mold may include an ONSNO stack. Here, the ONSNO stack may refer to a structure in which a first oxide, a first nitride, a monocrystalline silicon layer, a second nitride, and a second oxide are sequentially stacked. First and second silicon oxides may correspond to the second dielectric layers 19, and first and second silicon nitrides may correspond to the first dielectric layers 18. The monocrystalline silicon layer may correspond to the preliminary horizontal layer patterns 14A.

By a series of the processes illustrated in FIGS. 4 to 7 described above, the sub-stacks SB1 to SB5 of the stack body SB may be replaced with cell molds. The first layer 12A, the second layer 13, and the third layer 12B of each of the sub-stacks SB1 to SB5 may be replaced with the first dielectric layers 18 and the second dielectric layers 19. The preliminary horizontal layer 14 may become the preliminary horizontal layer pattern 14A.

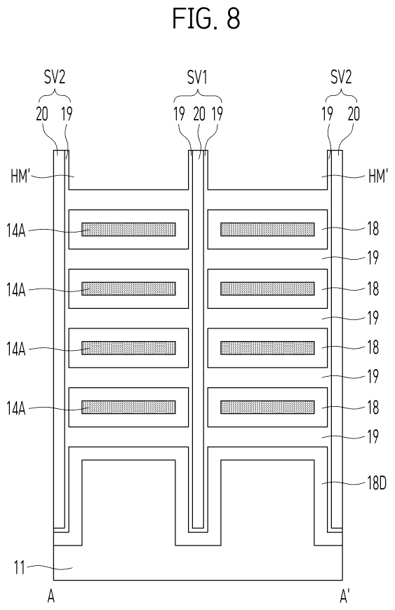

Referring to FIG. 8, the hard mask layer pattern HM1 of FIG. 7 may be removed to form a hard mask layer level opening HM′.

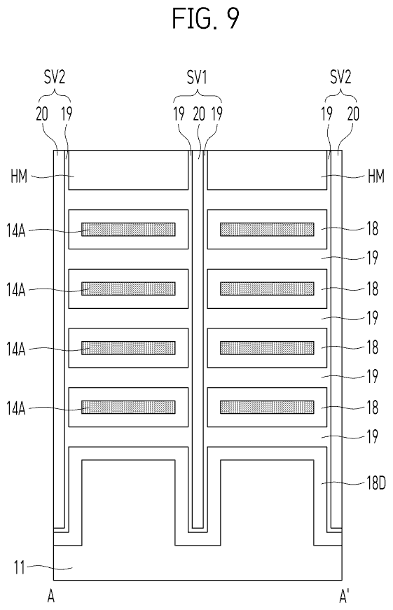

Referring to FIG. 9, the top dielectric layers HM may fill the hard mask layer level opening HM′ of FIG. 8. The top dielectric layers HM may include silicon oxide.

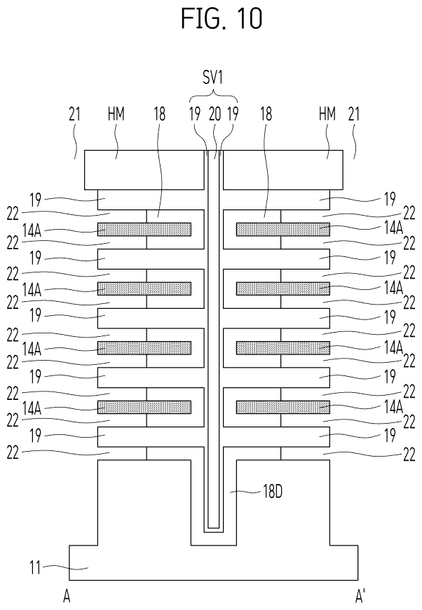

Referring to FIG. 10, the second sacrificial pillar structures SV2 of FIG. 9 may be removed to form first hole-shaped vertical openings 21. The first hole-shaped vertical openings 21 may be formed by selectively etching the second dielectric layer 19 and the sacrificial pillars 20.

Subsequently, the second dielectric layers 19 may be horizontally recessed. Subsequently, the first dielectric layers 18 may be horizontally recessed. The recess amount of the first dielectric layers 18 may be greater than the recess amount of the second dielectric layers 19. A portion of the first dielectric layers 18 may be recessed to form a dummy dielectric layer 18D on the substrate 11.

As a result of the recess process of the first dielectric layers 18, the first dielectric layer level recesses 22 may be formed. Portions of the preliminary horizontal layer patterns 14A may be exposed by the first dielectric layer level recesses 22.

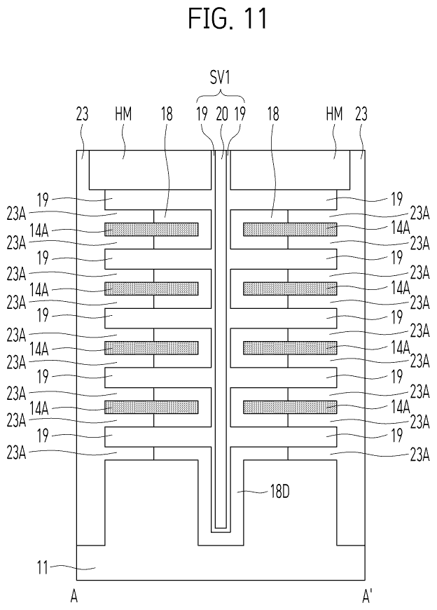

Referring to FIG. 11, first vertical sacrificial structures 23 may be formed to fill the first dielectric layer level recesses 22 and the first hole-shaped vertical openings 21 of FIG. 10. The first vertical sacrificial structure 23 may include a dielectric material. The first vertical sacrificial structure 23 may include silicon oxide, silicon nitride, titanium nitride, amorphous carbon, or a combination thereof. Each of the first vertical sacrificial structures 23 may include a body portion that fills the first hole-shaped vertical openings 21 and expanded portions 23A that fill the first dielectric layer level recesses 22.

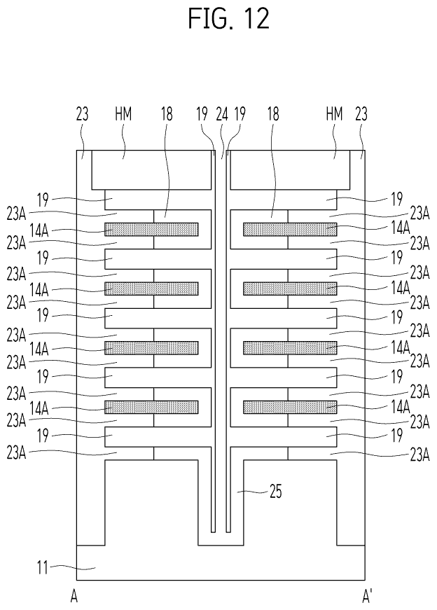

Referring to FIG. 12, the sacrificial pillar 20 of the first sacrificial pillar structure SV1 of FIG. 11 may be removed to form a vertical level path 24.

Subsequently, in order to form a lower level gap 25, the dummy dielectric layer 18D below the vertical level path 24 of FIG. 11 may be removed.

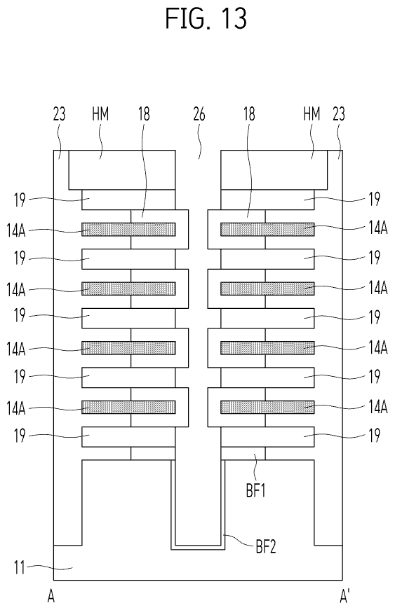

Referring to FIG. 13, a portion of the second dielectric layers 19 may be cut to form second hole-shaped vertical openings 26.

Subsequently, a first passivation layer BF1 may be formed to fill the lower level gap 25 of FIG. 12. The first passivation layer BF1 may include silicon oxide. Forming the first passivation layer BF1 may include depositing silicon oxide to fill the lower level gap 25 and etching the silicon oxide. Subsequently, a second passivation layer BF2 may be formed by oxidizing the surface of the first substrate 11.

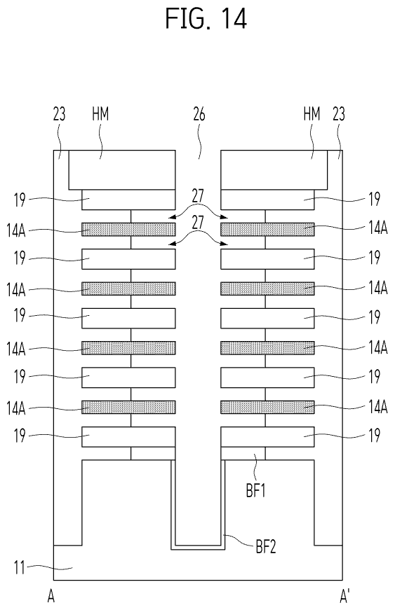

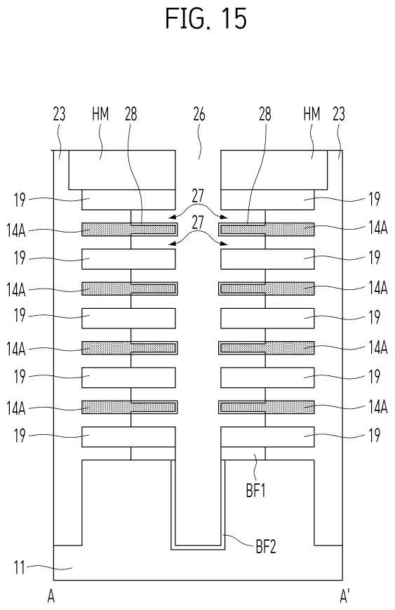

Referring to FIG. 14, the first dielectric layers 18 of FIG. 13 may be removed to form horizontal level recesses 27. Portions of the preliminary horizontal layer patterns 14A may be exposed by the horizontal level recesses 27. A portion of one preliminary horizontal layer pattern 14A may be exposed by a pair of the horizontal level recesses 27.

Referring to FIG. 15, an inter-level dielectric layer 28 may be formed over the exposed portions of the preliminary horizontal layer patterns 14A. The inter-level dielectric layer 28 may be formed by oxidizing the surface of the preliminary horizontal layer patterns 14A. According to another embodiment of the present disclosure, the inter-level dielectric layer 28 may be formed by a deposition process of silicon oxide.

The inter-level dielectric layer 28 may include silicon oxide, silicon nitride, a metal oxide, a metal oxynitride, a metal silicate, a high-k material, a ferroelectric material, an anti-ferroelectric material, or a combination thereof. The inter-level dielectric layer 28 may include SiO₂, Si₃N₄, HfO₂, Al₂O₃, ZrO₂, AlON, HfON, HfSiO, HfSiON, or a combination thereof.

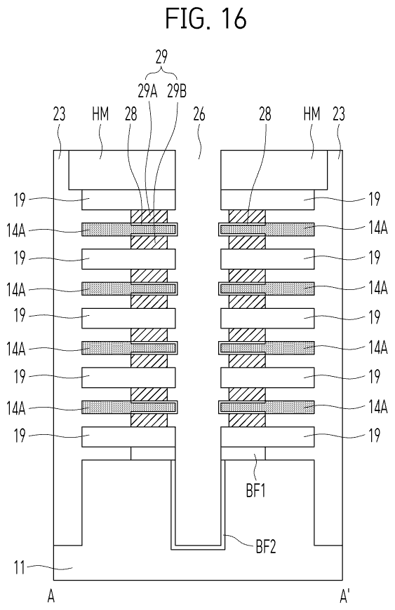

Referring to FIG. 16, a horizontal conductive line 29 may be formed over the inter-level dielectric layer 28 to fill the horizontal level recesses 27. Forming the horizontal conductive line 29 may include depositing a conductive material to fill the horizontal level recesses 27 over the inter-level dielectric layer 28 and performing an etch-back process of the conductive material. The horizontal conductive line 29 may include a pair of first and second horizontal conductive lines 29A and 29B that are facing each other with the semiconductor layer pattern 14A interposed therebetween. The first and second horizontal conductive lines 29A and 29B may include a metal-based material, a semiconductor material, or a combination thereof. The first and second horizontal conductive lines 29A and 29B may include titanium nitride, tungsten, polysilicon, or a combination thereof. For example, the first and second horizontal conductive lines 29A and 29B may include a titanium nitride and tungsten (TiN/W) stack in which titanium nitride and tungsten are sequentially stacked. The first and second horizontal conductive lines 29A and 29B may include an N-type work function material or a P-type work function material. The N-type work function material may have a low work function of approximately 4.5 eV or less. The P-type work function material may have a high work function of approximately 4.5 eV or greater. As illustrated in FIGS. 1A to 1C, each of the first and second horizontal conductive lines 29A and 29B may have a cross shape and may include a channel overlapping portion WLP. The horizontal conductive line 29 may correspond to the second conductive line DWL as illustrated in FIGS. 1A to 3. The first and second horizontal conductive lines 29A and 29B may correspond to the upper and lower horizontal lines G1 and G2 as illustrated in FIGS. 1A to 2D.

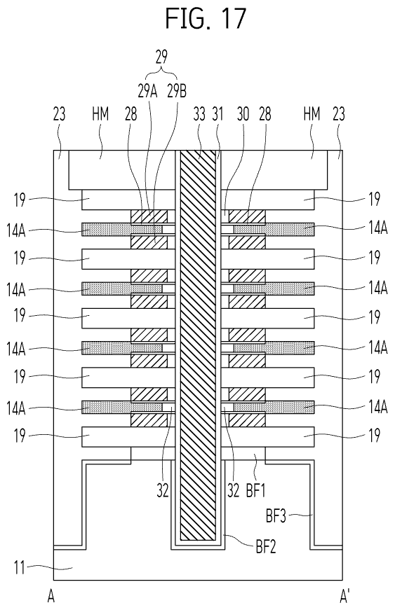

Referring to FIG. 17, a vertical conductive line 33 commonly coupled to the preliminary horizontal layer patterns 14A may be formed. The vertical conductive line 33 may fill the second hole-shaped vertical openings 26 of FIG. 16. The vertical conductive line 33 may include titanium nitride, tungsten, or a combination thereof. The vertical conductive line 33 may include a bit line. The vertical conductive line 33 may correspond to the first conductive line BL as illustrated in FIGS. 1A to 3B.

Before the vertical conductive line 33 is formed, a first contact node 31 may be formed. The first contact node 31 may include a metal-based material or a semiconductor material. The first contact node 31 may include doped polysilicon. Impurities may be diffused from the first contact node 31, thereby forming first doped regions 32 on one side of the preliminary horizontal layer patterns 14A.

Before the first contact node 31 is formed, a first capping layer 30 may be formed. The first capping layer 30 may be formed on one side of the horizontal conductive line 29. The first capping layer 42 may include silicon oxide, silicon nitride, or a combination thereof.

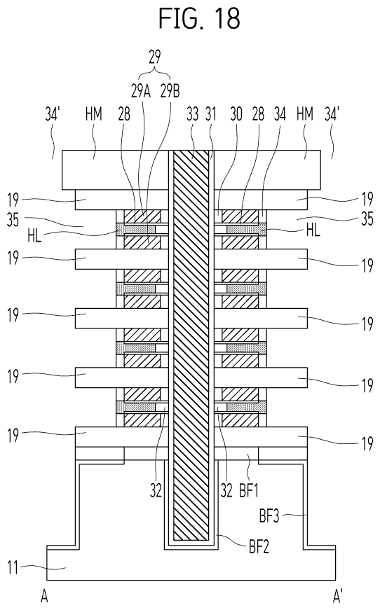

Referring to FIG. 18, the body portion of the first vertical sacrificial structure 23 of FIG. 17 may be removed to form the expanded hole-shaped openings 34′. Subsequently, a third passivation layer BF3 may be formed on the surface of the first substrate 11. The third passivation layer BF3 may include silicon oxide.

Subsequently, in order to form storage openings 35, the expanded portion of the first vertical sacrificial structure 23 and the preliminary horizontal layer patterns 14A may be trimmed horizontally from the expanded hole-shaped openings 34. The expanded portion of the first vertical sacrificial structure 23 remaining after the storage openings 35 are formed may be simply referred to as the first capping layer 34, and the remaining preliminary horizontal layer patterns 14A may be simply referred to as the horizontal layer HL. The horizontal layer HL may have a cross shape from the perspective of a top view.

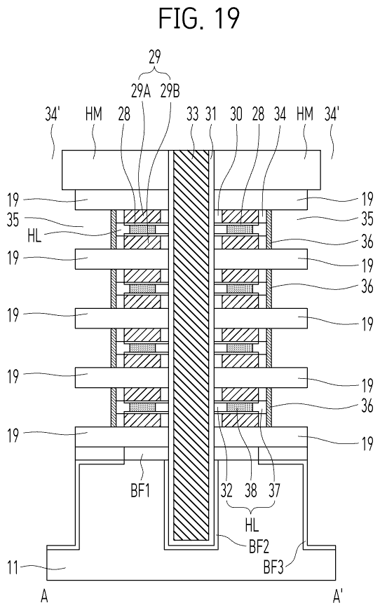

Referring to FIG. 19, a second contact node 36 may be formed over a second edge of the horizontal layer HL. The second contact node 36 may include doped polysilicon. Impurities may be diffused from the second contact node 36, thereby forming second doped regions 37 on a second side of the horizontal layer HL. The second contact node 36 may be referred to as an inner contact node.

The horizontal layer HL may include a first doped region 32, a second doped region 37, and a channel 38. The channel 38 may be defined between the first doped region 32 and the second doped region 37. The channel 38 may overlap vertically with the horizontal conductive line 29. The channel 38 may correspond to the channel CH as illustrated in FIGS. 1A to 2D.

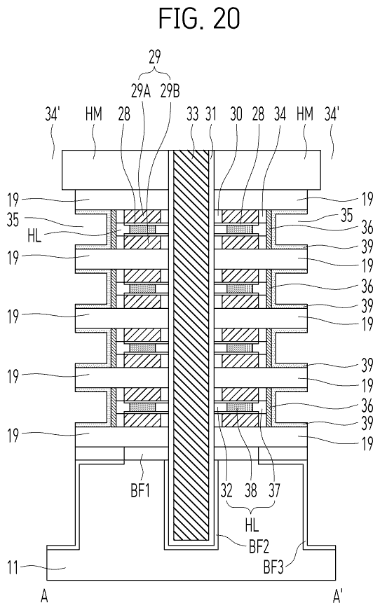

Referring to FIG. 20, a first electrode 39 of a data storage element may be formed over the second contact node 36. The first electrode 39 may have a horizontally oriented cylindrical shape.

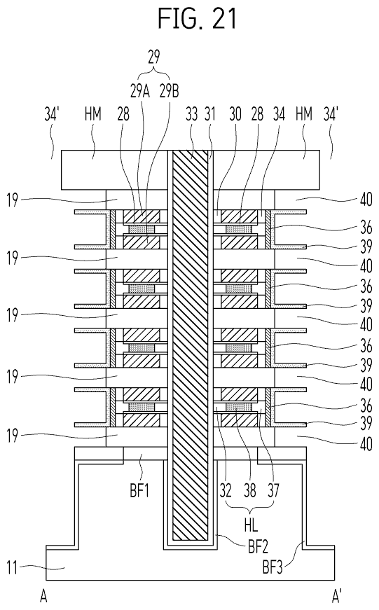

Referring to FIG. 21, the second dielectric layers 19 may be horizontally recessed (see a reference numeral ‘40’). As a result, the outer walls of the first electrodes 39 may be exposed.

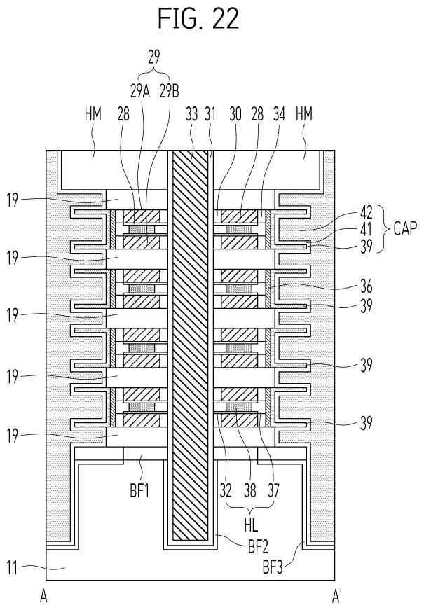

Referring to FIG. 22, a dielectric layer 41 and a second electrode 42 may be sequentially formed over the first electrodes 39. The first electrode 39, the dielectric layer 41, and the second electrode 42 may become a data storage element CAP.

The first electrode 39 may include an inner space and a plurality of outer surfaces. The inner space of the first electrode 39 may include a plurality of inner surfaces. The outer surfaces of the first electrode 39 may include vertical outer surfaces and a plurality of horizontal outer surfaces. The inner space of the first electrode 39 may be a three-dimensional space. The dielectric layer 41 may conformally cover the inner surfaces and the outer surfaces of the first electrode 39. The second electrode 42 may be disposed in the inner space of the first electrode 39 over the dielectric layer 41. Some of the outer surfaces of the first electrode 39 may be coupled to the horizontal layer HL.

The first electrode 39 may have a cylindrical shape. The cylindrical shape of the first electrode 39 may include cylindrical inner surfaces and cylindrical outer surfaces. The dielectric layer 41 and the second electrode 42 may be disposed on the cylindrical inner surfaces of the first electrode 39.

Each of the first electrode 39 and the second electrode 42 may include a metal, a noble metal, a metal nitride, a conductive metal oxide, a conductive noble metal oxide, a metal carbide, a metal silicide, or a combination thereof. For example, each of the first electrode 39 and the second electrode 42 may include titanium (Ti), titanium nitride (TiN), titanium silicon nitride (TiSiN), tantalum (Ta), tantalum nitride (TaN), tungsten (W), tungsten nitride (WN), ruthenium (Ru), ruthenium oxide (RuO₂), iridium (Ir), iridium oxide (IrO₂), platinum (Pt), molybdenum (Mo), molybdenum oxide (MoO), a titanium nitride/tungsten (TiN/W) stack, a titanium nitride/titanium silicon nitride (TiN/TiSiN) stack, a tungsten nitride/tungsten (WN/W) stack, or a combination thereof. The second electrode 42 may also include a combination of a metal-based material and a silicon-based material. For example, the second electrode 42 may be a stack of titanium nitride/silicon germanium/tungsten nitride (TiN/SiGe/WN). In the titanium nitride/silicon germanium/tungsten nitride (TiN/SiGe/WN) stack, silicon germanium may be a gap-fill material filling the inner space of the first electrode 39, titanium nitride (TiN) may serve as the second electrode 42 of the data storage element CAP, and tungsten nitride may be a low-resistance material.

The dielectric layer 41 may be referred to as a capacitor dielectric layer or a memory layer. The dielectric layer 41 may include silicon oxide, silicon nitride, a high-k material, a perovskite material, a ferroelectric material, an anti-ferroelectric material, or a combination thereof. The dielectric layer 41 may include a high-k material, such as hafnium oxide (HfO₂), zirconium oxide (ZrO₂), aluminum oxide (Al₂O₃), lanthanum oxide (La₂O₃), titanium oxide (TiO₂), tantalum oxide (Ta₂O₅), niobium oxide (Nb₂O₅) or strontium titanium oxide (SrTiO₃). The dielectric layer 41 may include a ZA (ZrO₂/Al₂O₃) stack, a ZAZ (ZrO₂/Al₂O₃/ZrO₂) stack, a ZAZA (ZrO₂/Al₂O₃/ZrO₂/Al₂O₃) stack, a ZAZAZ (ZrO₂/Al₂O₃/ZrO₂/Al₂O₃/ZrO₂) stack, a HA (HfO₂/Al₂O₃) stack, a HAH (HfO₂/Al₂O₃/HfO₂) stack, a HAHA (HfO₂/Al₂O₃/HfO₂/Al₂O₃) stack, a HAHAH (HfO₂/Al₂O₃/HfO₂/Al₂O₃/HfO₂) stack, a HZAZH(HfO₂/ZrO₂/Al₂O₃/ZrO₂/HfO₂) stack, a ZHZAZHZ(ZrO₂/HfO₂/ZrO₂/Al₂O₃/ZrO₂/HfO₂/ZrO₂) stack, a HZHZ(HfO₂/ZrO₂/HfO₂/ZrO₂) stack, or AHZAZHA(Al₂O₃/HfO₂/ZrO₂/Al₂O₃/ZrO₂/HfO₂/Al₂O₃) stack.

According to another embodiment of the present disclosure, an interface control layer may be further formed between the first electrode 39 and the dielectric layer 41 to alleviate the leakage current. The interface control layer may include titanium oxide (TiO₂), tantalum oxide (Ta₂O₅), niobium oxide (Nb₂O₅), niobium nitride (NbN), or a combination thereof. The interface control layer may also be formed between the second electrode 42 and the dielectric layer 41.

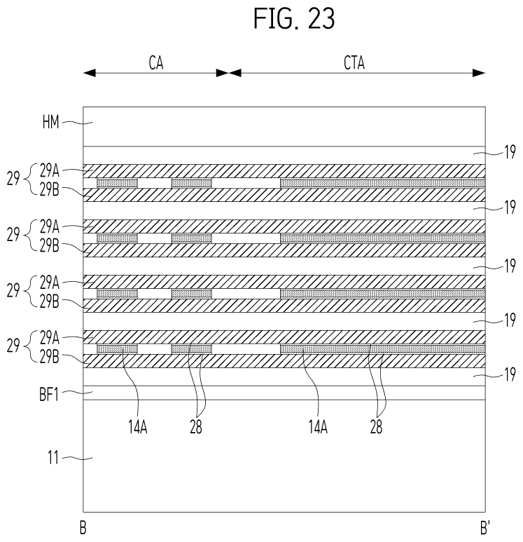

FIGS. 23 to 27 illustrate a method for forming a pad portion in accordance with an embodiment of the present disclosure. FIGS. 23 to 27 illustrate a method for forming a pad portion according to the line B-B′ shown in FIG. 2A. The pad portion forming process may be performed after the vertical conductive line 33 illustrated in FIG. 17 is formed.

Referring to FIGS. 4 to 17, after the horizontal conductive lines 29 and the vertical conductive line 33 are formed, the pad portion may be formed at an edge of one side of the horizontal conductive lines 29.

Referring to FIG. 23, the horizontal conductive lines 29 may include a pair of a first horizontal conductive line 29A and a second horizontal conductive line 29B. A plurality of horizontal conductive lines 29 may be stacked in the first direction D1. The preliminary horizontal layer pattern 14A and the inter-level dielectric layer 28 may be formed in the first region CA and the second region CTA, respectively. Second dielectric layers 19 may be formed between the horizontal conductive lines 29.

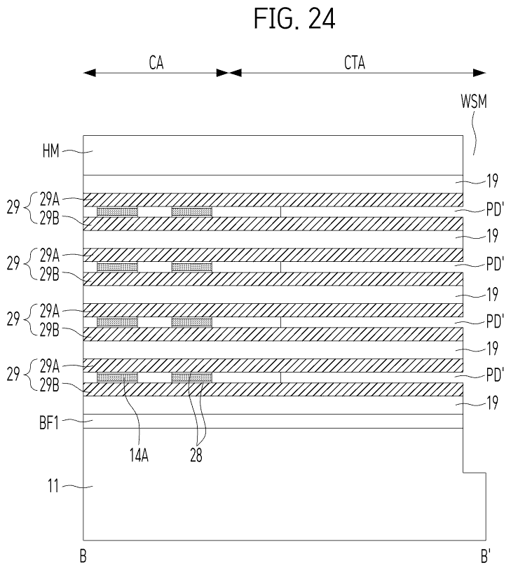

Referring to FIG. 24, the horizontal conductive lines 29 and the second dielectric layers 19 may be etched to form a pad isolation slit WSM in the second region CTA.

The inter-level dielectric layer 28 and the preliminary horizontal layer patterns 14A of FIG. 23 may be removed through the pad isolation slit WSM. As a result, pad-shaped recesses PD′ may be formed between the first horizontal conductive line 29A and the second horizontal conductive line 29B.

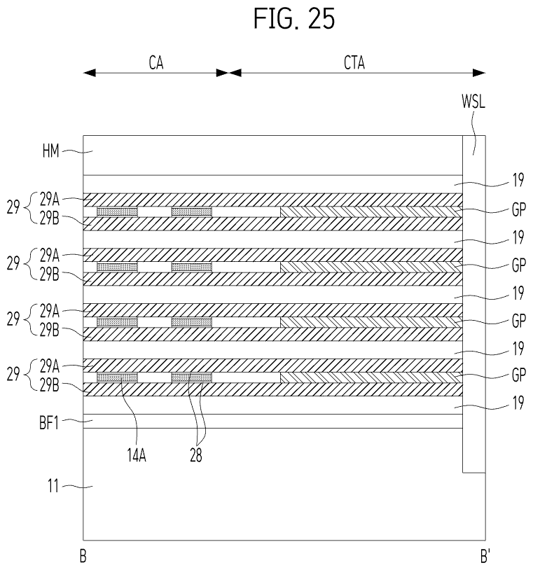

Referring to FIG. 25, pads GP filling the pad-shaped recesses PD′ of FIG. 24 may be formed.

Each horizontal conductive line 29 may include a pair of the first horizontal conductive line 29A and the second horizontal conductive line 29B. Each pad GP may be electrically connected to the first horizontal conductive line 29A and the second horizontal conductive line 29B.

The pads GP, the first horizontal conductive lines 29A and the second horizontal conductive lines 29B may include the same material. The pads GP, the first horizontal conductive lines 29A, and the second horizontal conductive lines 29B may include a metal-based material. For example, the pads GP, the first horizontal conductive lines 29A, and the second horizontal conductive lines 29B may include titanium nitride, tungsten, or a combination thereof. The pads GP, the first horizontal conductive lines 29A, and the second horizontal conductive lines 29B may include a metal-based material.

After the pads GP are formed, a slit WSL filling the pad isolation slit WSM may be formed. The slit WSL may include a dielectric material.

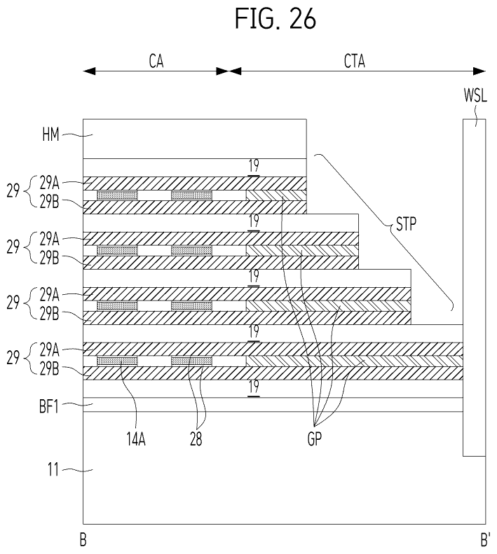

Referring to FIG. 26, the pads GP, the first horizontal conductive lines 29A, and the second horizontal conductive lines 29B may be etched to form a stair structure STP.

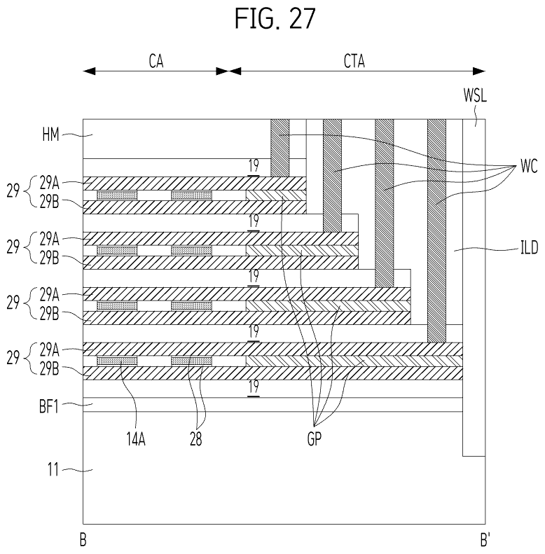

Referring to FIG. 27, after an inter-layer dielectric layer ILD covering the stair structure STP is formed, cell contact plugs WC coupled to the horizontal conductive lines 29 of the respective levels may be formed. The cell contact plugs WC may include a metal-based material.

A memory cell array may be formed in the first substrate 11 by a series of the processes as illustrated in FIGS. 4 to 27. Hereinafter, for the detailed description of the constituent elements of the memory cell array, FIGS. 1A to 27 may be referred to.

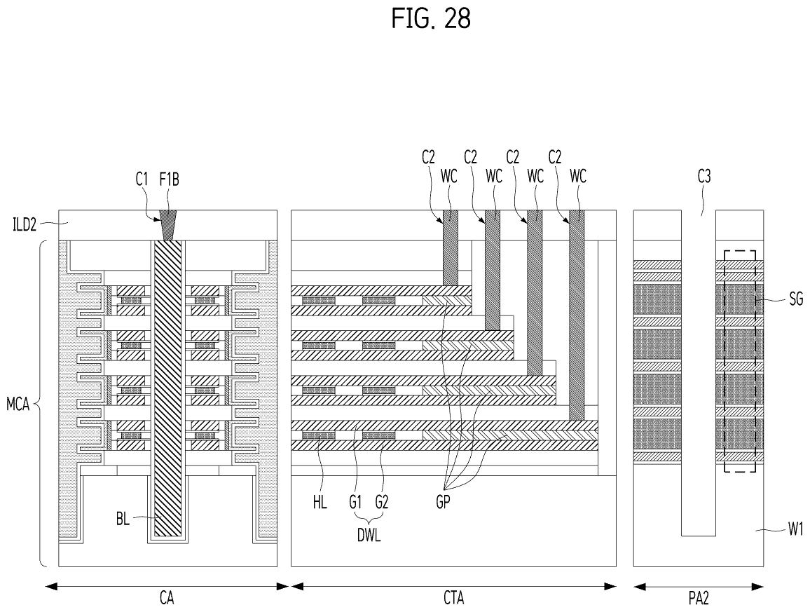

FIGS. 28 to 33 illustrate a method for fabricating the semiconductor device shown in FIG. 3.

Referring to FIG. 28, a first substrate W1 including a memory cell array MCA and a dummy stack SG may be prepared. The dummy stack SG may include silicon layers and silicon germanium layers. The dummy stack SG may correspond to the stack body SB as illustrated in FIG. 4. Hereinafter, for the detailed description of the constituent elements of the memory cell array MCA and the dummy stack SG, FIGS. 1A to 27 may be referred to. The memory cell array MCA may include a first region CA and a second region CTA.

A plurality of contact holes C1 and C2 may be formed. The contact holes may include a first contact hole C1 and second contact holes C2. The first contact hole C1 may be formed in the first region CA of the memory cell array MCA, and the second contact holes C2 may be formed in the second region CTA of the memory cell array MCA. The first contact hole C1 may expose an upper portion of a first conductive line BL of the memory cell array MCA. The second contact holes C2 may expose the steps of the second conductive lines DWL of the pad portion.

A front level plug F1B may be formed in the first contact hole C1, and cell contact plugs WC may be formed in the second contact holes C2.

After forming the front level plug F1B and the cell contact plugs WC, a third contact hole C3 may be formed in the dummy region PA2. The third contact hole C3 may pass through the dummy stack SG of the dummy region PA2 and may extend into the interior of the first substrate W1. The third contact hole C3 may be referred to as a stack level contact hole.

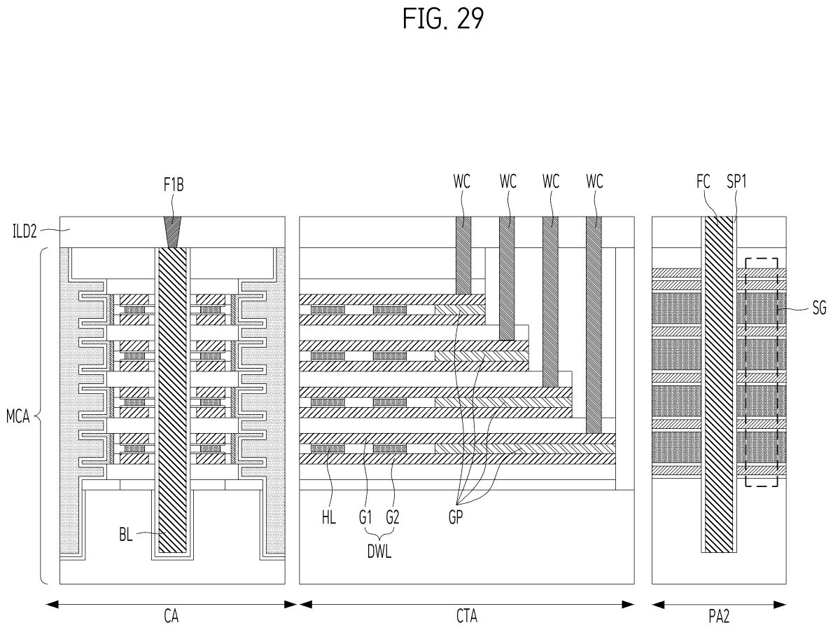

Referring to FIG. 29, a stack level plug FC may be formed in the third contact hole C3. Before the stack level plug FC is formed, a stack level spacer SP1 may be formed on a sidewall of the third contact hole C3 of FIG. 28.

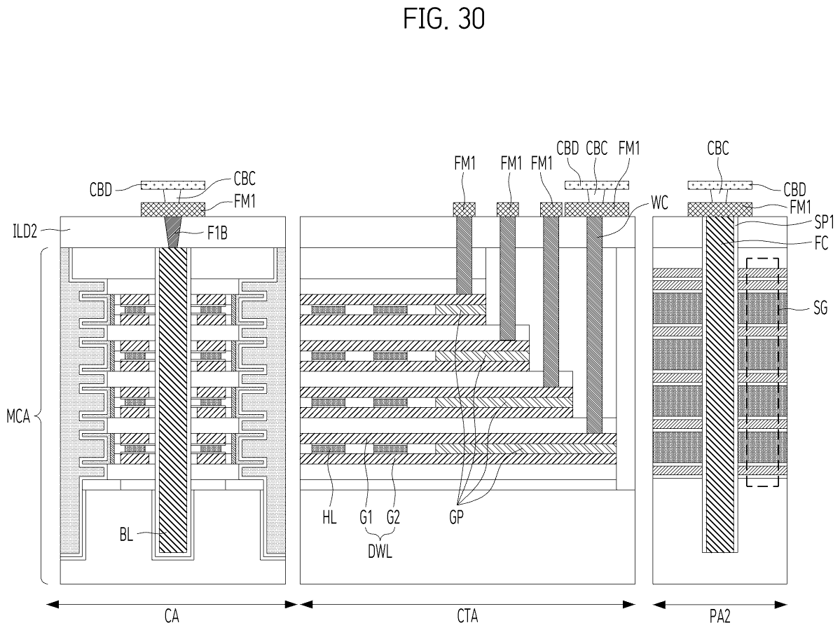

Referring to FIG. 30, front level interconnections FM1 may be formed over the front level plug F1B and the cell contact plug WC. The front level interconnections FM1 may be formed over the stack level plug FC. The front level interconnections FM1 may be formed over the memory cell array MCA and the dummy region PA2.

First bonding contact plugs CBC and first bonding pads CBD may be sequentially formed over the front level interconnections FM1.

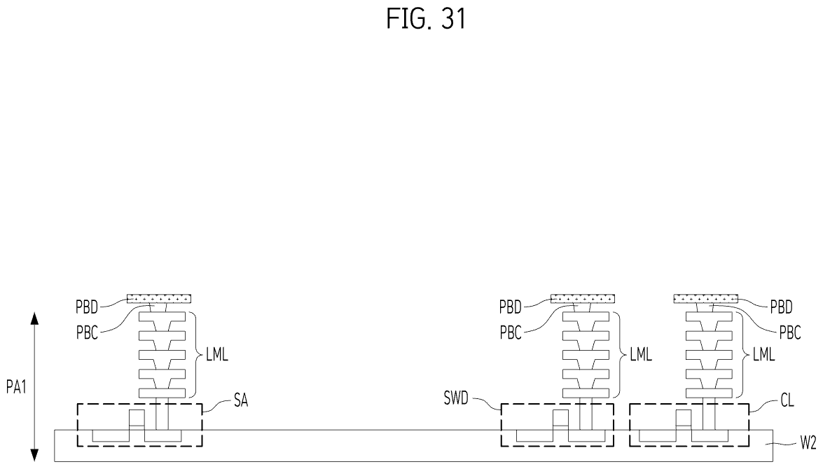

Referring to FIG. 31, a peripheral circuit region PA1 may be prepared. The peripheral circuit region PA1 may be formed with a peripheral control circuit CL, a sub-word line driver SWD, and a sense amplifier SA over a second substrate W2. The peripheral control circuit CL, the sub-word line driver SWD, and the sense amplifier SA may include transistors.

A first multi-layer level interconnection LML may be formed over the peripheral control circuit CL, the sub-word line driver SWD, and the sense amplifier SA.

Second bonding contact plugs PBC and second bonding pads PBD may be sequentially formed over the first multi-layer level interconnection LML.

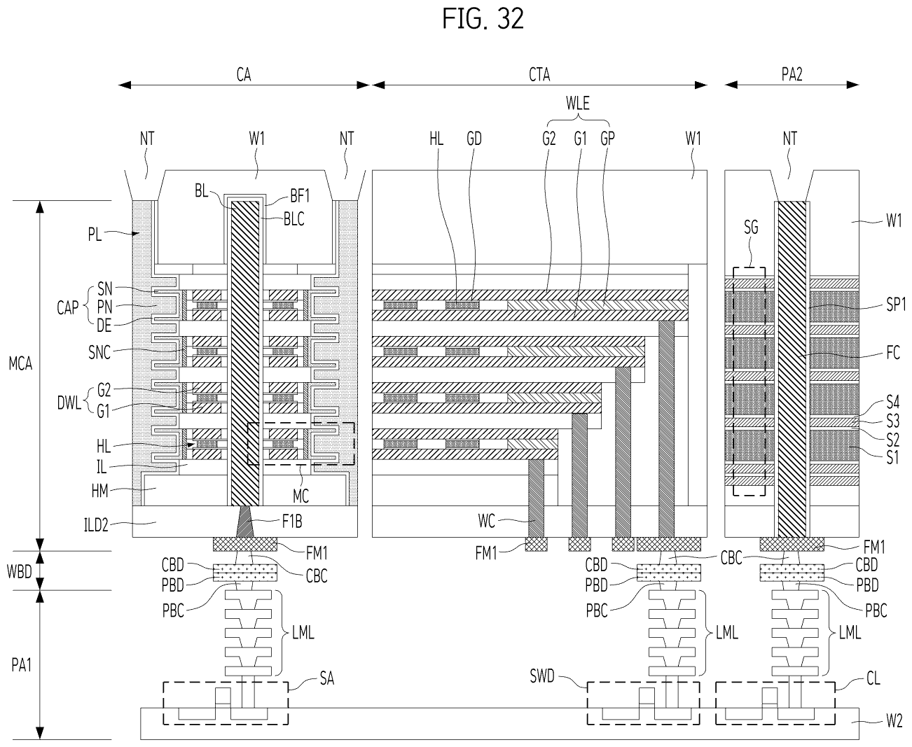

Referring to FIG. 32, a wafer bonding process may be performed to bond the memory cell array MCA and the peripheral circuit region PA1. For example, the first substrate W1 may be turned over to bond the memory cell array MCA and the peripheral circuit region PA1 with each other. Also, the first substrate W1 may be turned over to bond the dummy region PA2 and the peripheral circuit region PA1. The memory cell array MCA and the peripheral circuit region PA1 may be bonded by bonding structure WBD of the first bonding pads CBD and the second bonding pads PBD. The dummy region PA2 and the peripheral circuit region PA1 may be bonded by bonding structure WBD of the first bonding pads CBD and the second bonding pads PBD.

Subsequently, a plurality of nano-through holes NT may be formed on the back side of the first substrate W1. The nano-through holes NT may be formed by partially etching the back side of the first substrate W1.

The nano-through holes NT may expose the back sides of the common plates PL and the stack level plugs FC.

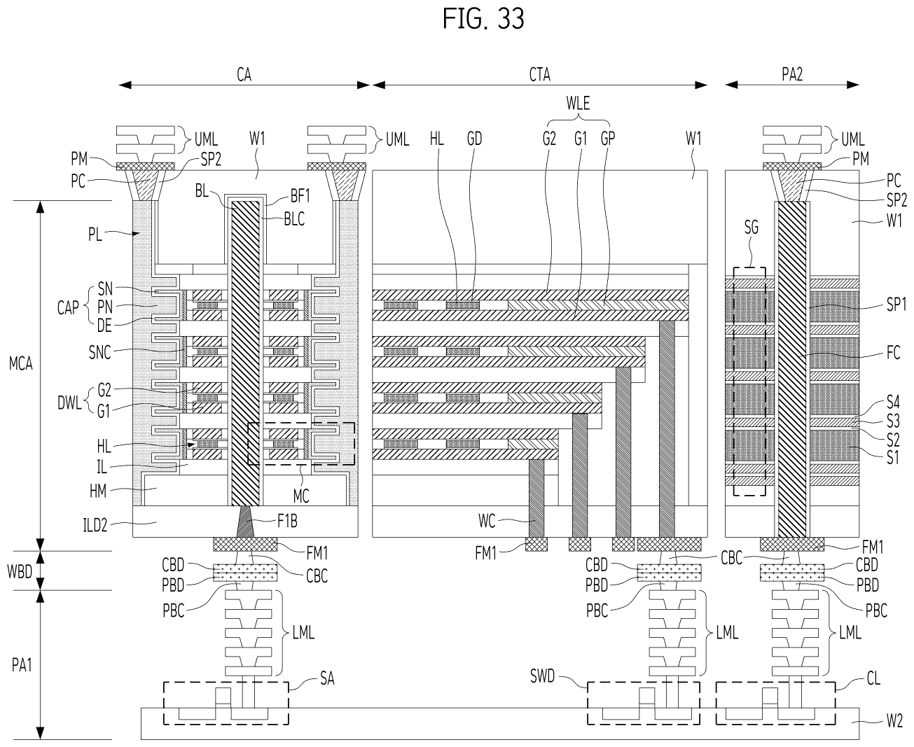

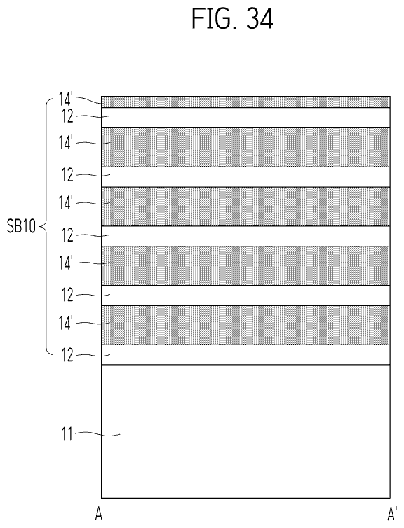

Referring to FIG. 33, a nano-through silicon via PC and post-level interconnections PM may be formed. The nano-through silicon via PC may fill the nano-through holes NT. Before the nano-through silicon vias PC are formed, a nano-level spacer SP2 may be formed on the sidewalls of the nano-through holes NT.

A second multi-layer level interconnection UML may be formed over the post-level interconnections PM.

The common plate PL of the data storage elements CAP of the memory cell array MCA may be coupled to the second multi-layer level interconnection UML through the nano-through silicon via PC and the post-level interconnection PM. The nano-through silicon via PC may penetrate the back side of the first substrate W1. The nano-level spacers SP2 may be formed on the sidewalls of the nano-through silicon vias PC.

The stack level plug FC may be coupled to the second multi-layer level interconnection UML through the nano-through silicon via PC and the post-level interconnection PM.

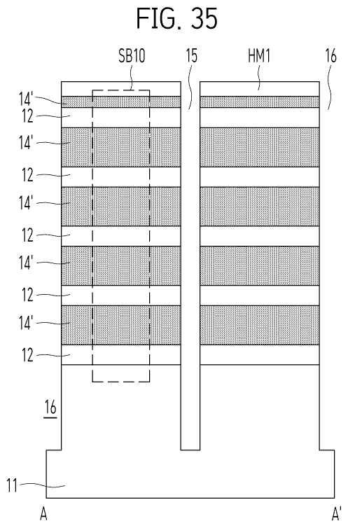

FIGS. 34 to 36 are cross-sectional views illustrating a method for fabricating a semiconductor device in accordance with another embodiment of the present disclosure.

Referring to FIG. 34, a stack body SB10 may be formed over the first substrate 11. The stack body SB10 may include an alternating stack of first semiconductor layers and second semiconductor layers. For example, the alternating stack may include a plurality of silicon germanium layers 12 and a plurality of monocrystalline silicon layers 14′ that are alternately stacked by an epitaxial growth process. The silicon germanium layers 12 may be sacrificial layers, and the monocrystalline silicon layers 14′ may be recess target layers. The silicon germanium layers 12 may correspond to the first layers 12A or the third layers 12B of FIG. 4, and the monocrystalline silicon layers 14′ may correspond to the fourth layers 14 of FIG. 4. Unlike the stack body SB of FIG. 4, the stack body SB10 may have an alternating stack of the silicon germanium layers 12 and the monocrystalline silicon layers 14′.

Referring to FIG. 35, a hard mask layer pattern HM1 may be formed over the stack body SB10.

Subsequently, the stack body SB10 may be etched by using the hard mask layer pattern HM1 as an etching barrier. As a result, a plurality of first and second sacrificial vertical openings 15 and 16 may be formed in the stack body SB10.

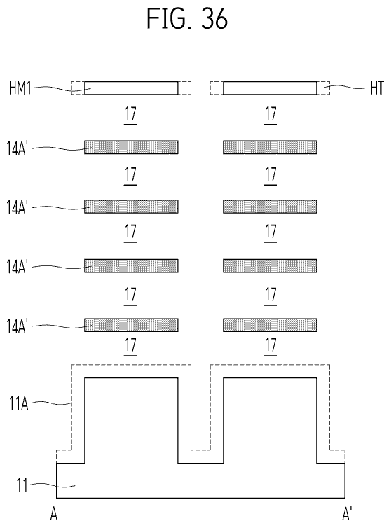

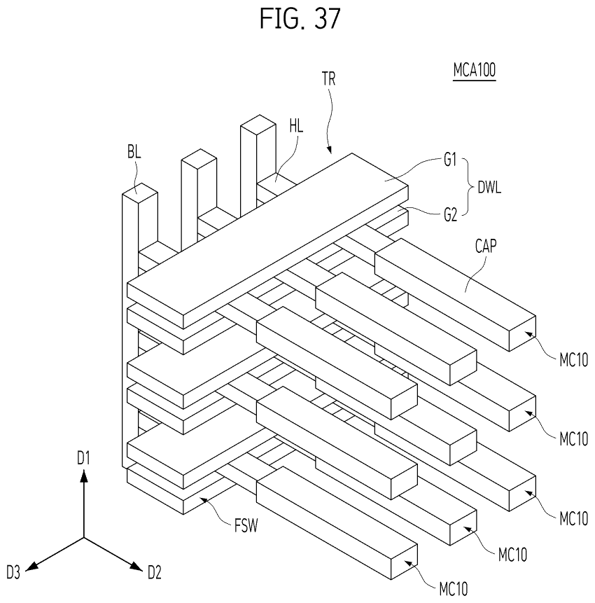

Referring to FIG. 36, preliminary horizontal layers 14A′ and horizontal recesses 17 may be formed. The preliminary horizontal layers 14A′ and the horizontal recesses 17 may be formed by a recess process of the silicon germanium layers 12 and the monocrystalline silicon layers 14′ of FIG. 35. After the silicon germanium layers 12 are removed, a recess process of the monocrystalline silicon layers 14′ may be performed. The preliminary horizontal layers 14A′ may correspond to the preliminary horizontal layers 14A of FIG. 6.

The silicon germanium layers 12 may be recessed by a wet etching process or a dry etching process. The silicon germanium layers 12 may be etched by using an etchant or etching gas having a selectivity with respect to the monocrystalline silicon layers 14′.

The recess process of the monocrystalline silicon layers 14′ for forming the preliminary horizontal layers 14A′ may use, for example, Hot SC-1 (HSC1). HSC1 may include a solution in which ammonium hydroxide (NH₄OH), hydrogen peroxide (H₂O₂), and water (H₂O) are mixed in a ratio of approximately 1:4:20. The monocrystalline silicon layers 14′ may be selectively etched by using the HSC1.

While the preliminary horizontal layers 14A′ are formed, the surface of the first substrate 11 may be recessed to a predetermined depth (see a reference numeral ‘11A’). As a result, the depths of the first and second sacrificial vertical openings 15 and 16 may be increased.

Subsequently, a series of the processes illustrated in FIGS. 8 to 22 may be performed.

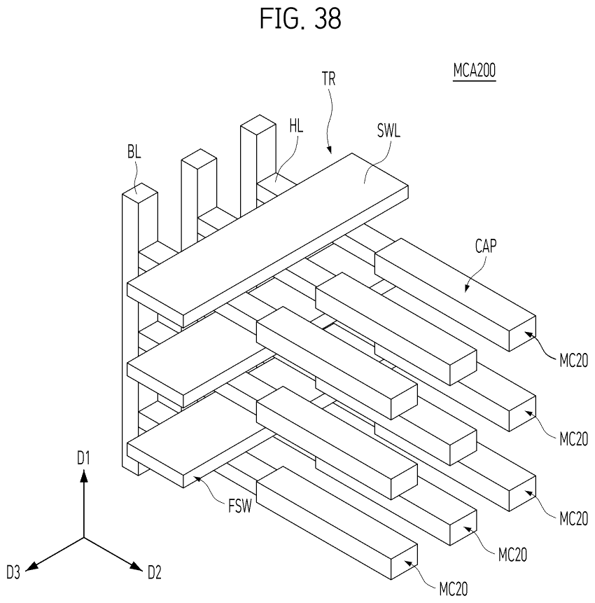

FIGS. 37 to 39 are perspective views illustrating memory cell arrays in accordance with other embodiments of the present disclosure. The memory cell arrays MCA100, MCA200 and MCA300 may be similar to the memory cell array MCA of FIG. 2C. Hereinafter, for the detailed descriptions of the constituent element also appearing in FIG. 2C, the above-described embodiments of the present disclosure may be referred to.

Referring to FIG. 37, the memory cell array MCA100 may include a plurality of memory cells MC10.

The memory cell array MCA100 may include a three-dimensional array of the memory cells MC10, which may include a column array of memory cells MC10 and a row array of memory cells MC10. The column array of the memory cells MC10 may have a plurality of memory cells MC10 that are stacked in the first direction D1. The row array of the memory cells MC10 may have a plurality of memory cells MC10 that are disposed horizontally in the second direction D2 and the third direction D3.

Each memory cell MC10 may include a first conductive line BL, a switching element TR, and a data storage element CAP. For the detailed description of the first conductive line BL and the data storage element CAP, the above-described embodiments of the present disclosure may be referred to.

The switching element TR may include a horizontal layer HL and a second conductive line DWL. The horizontal layer HL may extend in the second direction D2. The second conductive line DWL may extend in the third direction D3.

The second conductive line DWL may have a double structure. For example, the second conductive line DWL may include an upper horizontal line G1 and a lower horizontal line G2 that are facing each other with the horizontal layer HL interposed therebetween. As illustrated in FIG. 1B, an inter-level dielectric layer GD may be formed on the upper surface and the lower surface of the horizontal layer HL.

Each of the upper horizontal line G1 and the lower horizontal line G2 may include a pair of flat sidewalls FSW extending in the third direction D3. The flat sidewalls FSW may refer to the vertical sidewalls. The flat sidewalls FSW may have a linear shape extending in the third direction D3.

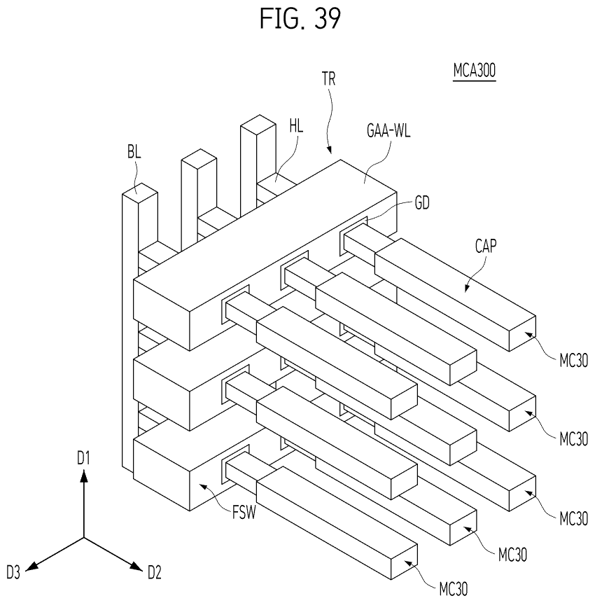

Referring to FIG. 38, the memory cell array MCA200 may include a plurality of memory cells MC20.

The memory cell array MCA200 may include a three-dimensional array of memory cells MC20. The three-dimensional array of the memory cells MC20 may include a column array of memory cells MC20 and a row array of memory cells MC20. The column array of the memory cells MC20 may include a plurality of memory cells MC20 that are stacked in the first direction D1. The row array of the memory cells MC20 may include a plurality of memory cells MC20 that are disposed horizontally in the second direction D2 and the third direction D3.

Each memory cell MC20 may include a first conductive line BL, a switching element TR, and a data storage element CAP. For the detailed descriptions of the first conductive line BL and the data storage element CAP, the above-described embodiments of the present disclosure may be referred to.

The switching element TR may include a horizontal layer HL and a second conductive line SWL. The horizontal layer HL may extend in the second direction D2. The second conductive line SWL may extend in the third direction D3.

The second conductive line SWL may be a single structure. For example, the second conductive line SWL may be disposed over the horizontal layer HL. As illustrated in FIG. 3, an inter-level dielectric layer GD may be formed between the upper surface of the horizontal layer HL and the second conductive line SWL. According to another embodiment of the present disclosure, the second conductive line SWL may be disposed below the horizontal layer HL.

The second conductive line SWL may include a pair of flat sidewalls FSW extending in the third direction D3. The flat sidewalls FSW may refer to the vertical sidewalls.

According to another embodiment of the present disclosure, the second conductive line SWL may include a channel overlapping portion WLP and a channel non-overlapping portion NOL, as illustrated in FIG. 1C.

Referring to FIG. 39, the memory cell array MCA300 may include a plurality of memory cells MC30.

The memory cell array MCA300 may include a three-dimensional array of memory cells MC30. The three-dimensional array of the memory cells MC30 may include a column array of memory cells MC30 and a row array of memory cells MC30. The column array of the memory cells MC30 may include a plurality of memory cells MC30 that are stacked in the first direction D1. The row array of the memory cells MC30 may include a plurality of memory cells MC30 that are disposed horizontally in the second direction D2 and the third direction D3.

Each memory cell MC30 may include a first conductive line BL, a switching element TR, and a data storage element CAP. For the detailed description of the first conductive line BL and the data storage element CAP, the above-described embodiments of the present disclosure may be referred to.

The switching element TR may include a horizontal layer HL and a second conductive line GAA-WL. The horizontal layer HL may extend in the second direction D2. The second conductive line GAA-WL may extend in the third direction D3.

The second conductive line GAA-WL may be a Gate All Around structure GAA. For example, the second conductive line GAA-WL may extend in the third direction D3 while surrounding the horizontal layers HL. An inter-level dielectric layer GD may be formed between the horizontal layer HL and the second conductive line GAA-WL. The inter-level dielectric layer GD may surround each of the horizontal layers HL.

The second conductive line GAA-WL may include a pair of flat sidewalls FSW extending in the third direction D3. The flat sidewall FSW may refer to a vertical sidewall.

According to another embodiment of the present disclosure, each memory cell may have a first conductive line BL extending horizontally in the third direction D3, a second conductive line DWL extending vertically in the first direction D1, and a horizontal layer HL extending horizontally in the second direction D2. The second conductive line DWL may have a double structure and may be replaced with a single structure or a gate-all-around structure.

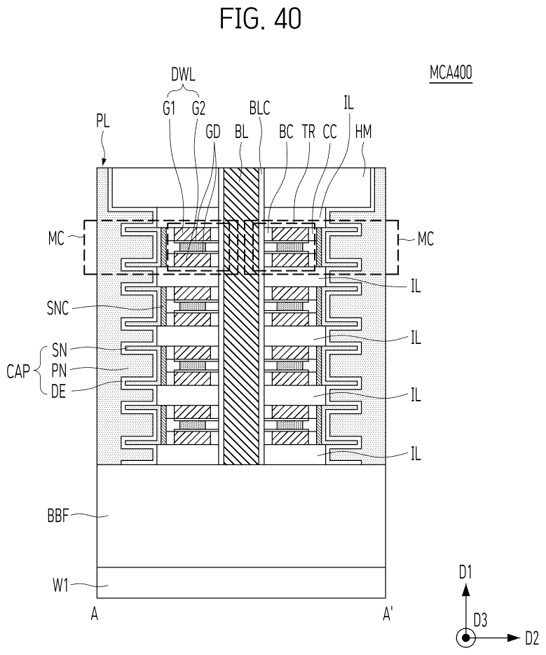

FIG. 40 is a cross-sectional view illustrating a memory cell array MCA400 in accordance with another embodiment of the present disclosure.

The memory cell array MCA400 of FIG. 40 may be similar to the memory cell MCA array of FIGS. 2A to 2D. Hereinafter, a detailed description of the constituent elements of the memory cell array MCA400 also appearing in the memory cell array MCA of FIGS. 2A to 2D may be omitted.

Referring to FIG. 40, a buried buffer layer BBF may fully cover the upper surface of a first substrate W1. The buried buffer layer BBF may include an oxide, such as silicon oxide. The first substrate W1 and the buried buffer layer BBF may have a Silicon-On-Insulator (SOI) structure.

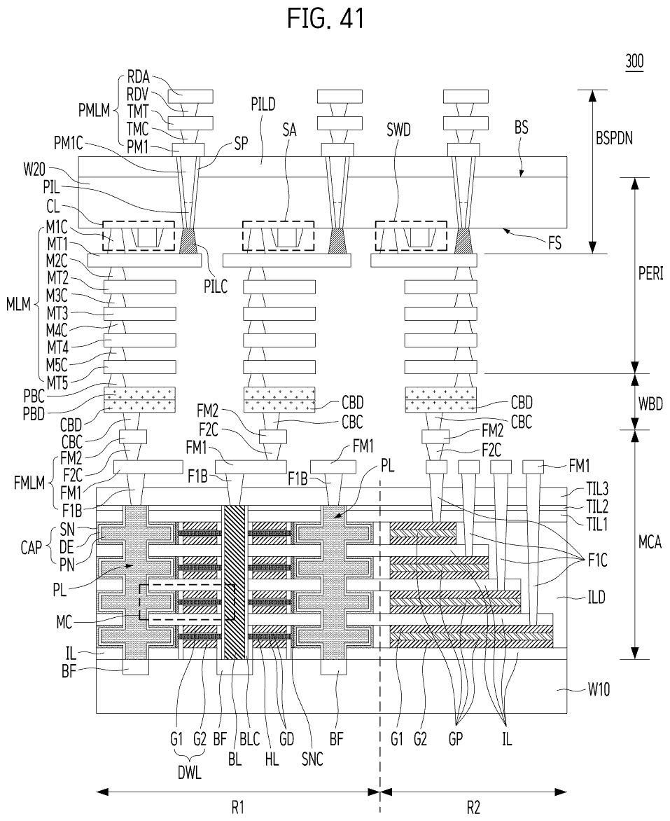

FIGS. 41 to 44 schematically illustrate a semiconductor device in accordance with another embodiment of the present disclosure.

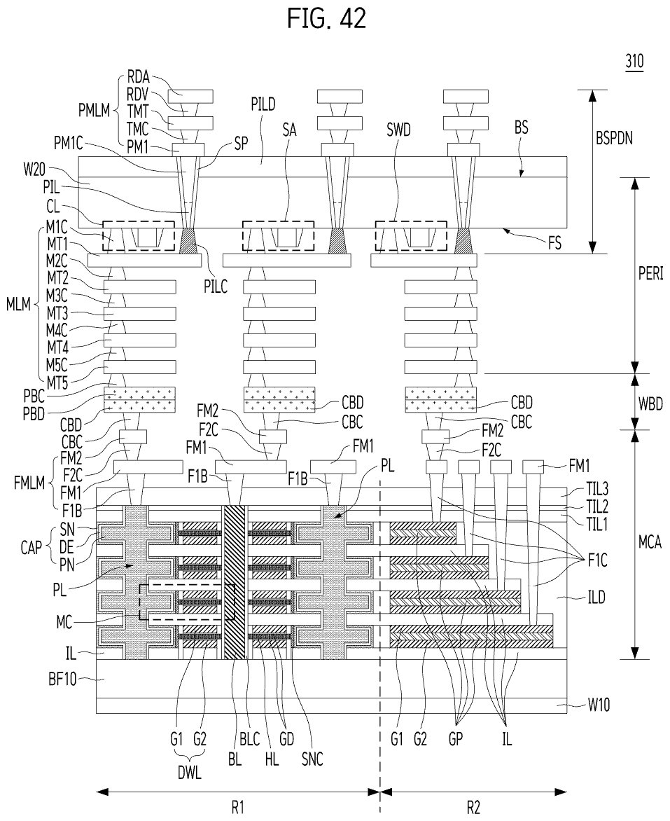

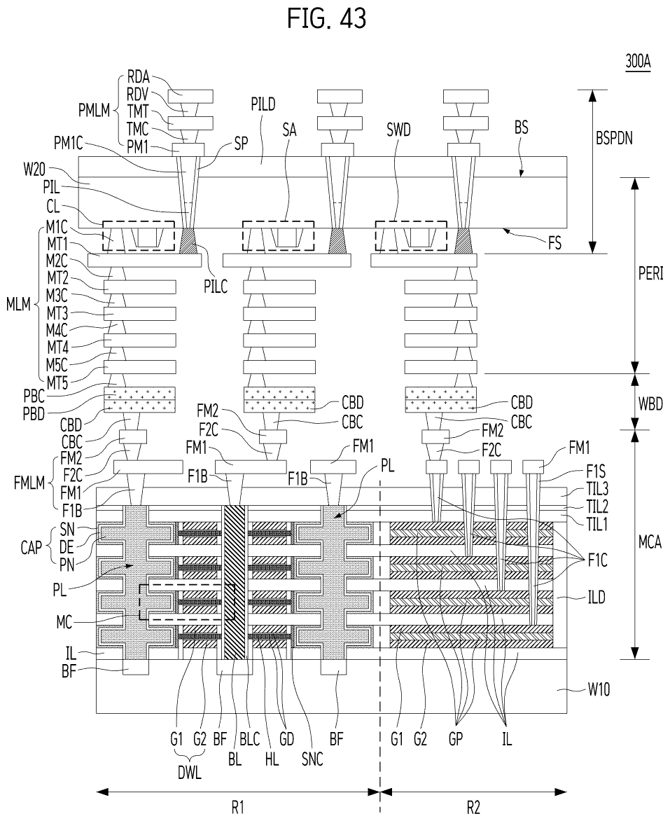

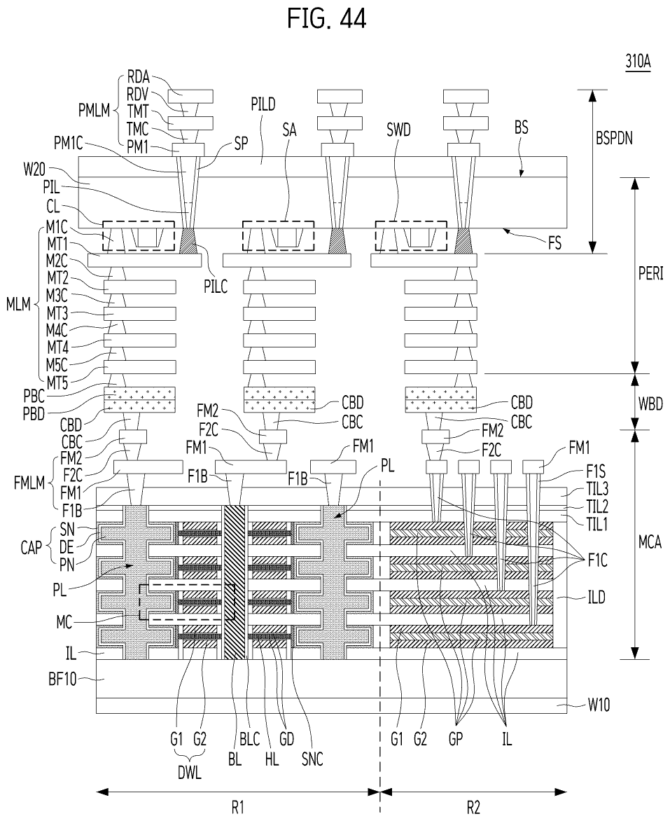

Referring to FIGS. 41 to 44, each of the semiconductor devices 300, 310, 300A, and 310A may include a memory cell array MCA, a peripheral circuit PERI, and a back-side interconnection structure BSPDN. The semiconductor device 300, 310, 300A, and 310A may further include a bonding structure WBD disposed between the memory cell array MCA and the peripheral circuit PERT. The semiconductor device 300 of FIG. 41 and the semiconductor device 310 of FIG. 42 may have the same constituent elements except the buffer layer BF and the buried buffer layer BF10. The semiconductor device 300A of FIG. 43 and the semiconductor device 310A of FIG. 44 may have the same constituent elements except the buffer layer BF and the buried buffer layer BF10. The semiconductor device 300, 310, 300A, and 310A may exclude the dummy stack SG which is illustrated in FIG. 3.

The memory cell array MCA may be similar to the memory cell array MCA of FIGS. 2A to 2D. Hereinafter, for the detailed description of the constituent elements of the memory cell array MCA, FIGS. 2A to 2D may be referred to. The memory cell array MCA may include a first substrate W10, a plurality of memory cells MC, and a front multi-level metal line FMLM.

The memory cell array MCA may include a first region R1 and a second region R2. The first region R1 may be a region where memory cells MC are formed, and the second region R2 may be a region where cell contact plugs coupled to the memory cells MC are formed. The second region R2 of the semiconductor device 300 and 310 may include a stair-shaped pad portion. The second region R2 of the semiconductor device 300A and 310A may include a stair-less pad portion.

The memory cells MC may be disposed over the first substrate W10. The front multi-level metal line FMLM may be disposed over the memory cells MC. The three-dimensional array of the memory cells MC may include a column array of memory cells MC and a row array of memory cells MC. The column array of the memory cells MC may include a plurality of memory cells MC that are stacked in the first direction D1. The row array of the memory cells MC may include a plurality of memory cells MC that are horizontally disposed in the second direction D2 and the third direction D3. The memory cell arrays may be vertically stacked in the first direction D1 over the first substrate W10. According to another embodiment of the present disclosure, the memory cell arrays may be horizontally disposed in the second direction D2 over the first substrate W10. The memory cell arrays may include a buried gate-based Dynamic Random Access Memory (DRAM), a three-dimensional (3D) DRAM, a 3D NAND, a flash memory, a Spin Transfer Torque Random Access Memory (STT-RAM), a Resistive Random Access Memory (RRAM), a Magnetic Random Access Memory (MRAM), a thyristor, a vertical gate-based DRAM, and the like. The front multi-level metal line FMLM may include a plurality of metal lines and a plurality of vias. The memory cell array MCA may include a plurality of top dielectric layers TIL1, TIL2, and TIL3. The upper surfaces of the first conductive line BL and the common plate PL may be disposed at the same level as the upper surface of the top dielectric layer TIL2. The front multi-level metal line FMLM of the memory cell array MCA may include first front vias F1B, first front level interconnections FM1, second front vias F2C, and second front level interconnections FM2. The first front vias F1B may penetrate the top dielectric layer TIL3 to be coupled to the first conductive line BL and the common plate PL, respectively. The second front level interconnections FM2 may be coupled to the first bonding contacts CBC and the first bonding pads CBD.

Referring to FIGS. 41 and 42, in the second region R2 of the memory cell array MCA, respective pad portion of the stair-shaped pad portion may include an upper horizontal line G1, a lower horizontal line G2, and a pad GP between the upper horizontal line G1 and the lower horizontal line G2. The pad portions of the stair-shaped pad portion may have different horizontal length. Inter-cell dielectric layers IL may be disposed between the pad portions. The inter-cell dielectric layers IL may include silicon oxide. The inter-cell dielectric layers IL may be referred to as horizontal inter-cell dielectric layers. The upper horizontal lines G1 of the stair-shaped pad portion may be respectively coupled to the first front contact plugs F1C and the first front level interconnection FM1. The first front contact plugs F1C may be referred to as cell contacts. The first front contact plugs F1C may penetrate the top dielectric layers TIL1, TIL2 and TIL3 and the inter-layer dielectric layer ILD. The first front contact plugs F1C may correspond to the cell contact plugs WC of FIG. 3.

Referring to FIGS. 43 and 44, in the second region R2 of the memory cell array MCA, respective pad portion of the stair-less pad portion may include an upper horizontal line G1, a lower horizontal line G2, and a pad GP between the upper horizontal line G1 and the lower horizontal line G2. The pad portions of the stair-less pad portion may have the same horizontal length. The upper horizontal lines G1 of the stair-less pad portion may be respectively coupled to the first front contact plugs F1C and the first front level interconnections FM1. Sidewall spacers F1S may be formed on the sidewalls of the first front contact plugs F1C. The sidewall spacers F1S may include a dielectric material.

A buffer layer BF may be disposed on the bottom surface of the first conductive line BL and the bottom surface of the common plate PL. The buffer layer BF may include an oxide, such as silicon oxide. The semiconductor device 310 of FIG. 42 may have a buried buffer layer BF10 that fully covers the upper surface of the first substrate W10. The buried buffer layer BF10 may include an oxide, such as silicon oxide. The first substrate W10 and the buried buffer layer BF10 may have a Silicon-On-Insulator (SOI) structure.

The peripheral circuit PERI may include a second substrate W20, a plurality of control circuits CL, SA and SWD disposed on a lower level surface of the second substrate W20, and a multi-level metal line MLM coupled to the control circuits CL, SA and SWD. The multi-level metal line MLM may include a plurality of metal lines MT1 to MT5 and a plurality of metal contact plugs M1C to M5C. The multi-level metal line MLM may include at least a first level metal line MT1 and a first level metal contact plug M1C. The first level metal line MT1 and the first level metal contact plug M1C may be coupled to the control circuits CL, SA and SWD.

The peripheral circuit PERI may include at least one or more control circuits for driving the memory cell array MCA. The one or more control circuits of the peripheral circuit PERI may include an N-channel transistor, a P-channel transistor, a CMOS circuit, or a combination thereof. The one or more control circuits of the peripheral circuit PERI may include an address decoder circuit, a read circuit, a write circuit, and the like. The one or more control circuits of the peripheral circuit PERI may include a planar channel transistor, a recess channel transistor, a buried gate transistor, a fin channel transistor (FinFET), and the like.

For example, the peripheral circuit PERI may include a common plate control circuit CL, sub-word line drivers SWD, and a sense amplifier SA. A first conductive line BL of the memory cell array MCA may be coupled to the sense amplifier SA. Second conductive lines DWL may be coupled to the sub-word line drivers SWD. The common plates PL may be coupled to the common plate control circuit CL. Each of the transistors for the common plate control circuit CL, the sub-word line drivers SWD, and the sense amplifier SA may include a gate, a gate spacer, and source/drain.

The back-side interconnection structure BSPDN may include the second substrate W20, a power interconnection line PIL embedded in the second substrate W20, a power contact plug PILC coupled to a first surface of the power interconnection line PIL, a power via PM1C coupled to a second surface of the power interconnection line PIL, and a post-multi-level metal line PMLM disposed over the power via PM1C. The post-multi-level metal line PMLM may include a plurality of metal lines PM1, TMT and RDA and a plurality of vias TMC and RDV. The power interconnection line PIL and the power via PM1C may have an integral structure. A sidewall of the power interconnection line PIL and a sidewall of the power via PM1C may be surrounded by a power level spacer SP. The power interconnection line PIL is embedded in the second substrate W20, and sidewalls of the power interconnection line PIL are fully surrounded by and isolated from the second substrate W20 by the power level spacer SP. The second substrate W20 may include a front side FS and a back side BS. The second substrate W20 may be turned over by a wafer flip so that the back side BS is disposed over the front side FS. Accordingly, the front side FS of the second substrate W20 may refer to a surface facing the multi-level metal line MLM and the memory cell array MCA, and the back side BS of the second substrate W20 may refer to a surface facing the post-multi-level metal line PMLM.

A post-inter-layer dielectric layer PILD may be formed on the back side BS of the second substrate W20. The power via PM1C may expand into the interior of the second substrate W20 by passing through the post-inter-layer dielectric layer PILD. The power via PM1C may have a low aspect ratio. The power via PM1C may be referred to as a ‘nano-through silicon via NTSV’. The power interconnection line PIL may be referred to as a buried power rail BPR. The power contact plug PILC may be referred to as a buried power rail via that lands on the power interconnection line PIL, that is, a ‘via-to-buried power rail (Via-to-BPR) VBPR’. The vertical structure of the power via PM1C, the power interconnection line PIL and the power contact plug PILC may be a structure passing through the post-inter-layer dielectric layer PILD and the second substrate W20. The power contact plug PILC may be coupled to a multi-level metal line MLM. The power contact plug PILC may be coupled to a first level metal line MT1 of the multi-level metal line MLM. The first level metal contact plug M1C and the power contact plug PILC may be disposed at the same level.

The back-side interconnection structure BSPDN may be a back-side power distribution network that directly supplies power from the back side of the second substrate W20. The back-side interconnection structure BSPDN may supply the power to the control circuits CL, SA and SWD of the peripheral circuit PERI. The back-side interconnection structure BSPDN and the peripheral circuit PERI may share the second substrate W20. The back-side interconnection structure BSPDN may be coupled to the peripheral circuit PERI passing through the second substrate W20 from the back side BS of the second substrate W20.

The wafer bonding structure WBD may include a first bonding pad CBD coupled to the memory cell array MCA, and a second bonding pad PBD coupled to the peripheral circuit PERI. The wafer bonding structure WBD may further include a first bonding contact CBC and a second bonding contact PBC. The first bonding contact CBC may be coupled to the front multi-level metal line FMLM of the memory cell array MCA and the first bonding pad CBD. The second bonding contact PBC may be coupled to the multi-level metal line MLM of the peripheral circuit PERI and the second bonding pad PBD.

Bonding dielectric layers may be disposed between the first bonding pads CBD of the same level, and the bonding dielectric layers may be disposed between the second bonding pads PBD of the same level. The first bonding pad CBD and the second bonding pad PBD may be coupled by direct bonding or hybrid bonding. Direct bonding may mean that the first bonding pad CBD and the second bonding pad PBD are directly bonded, for example, it may refer to metal-to-metal bonding. Hybrid bonding may refer to a combination of metal-to-metal bonding and dielectric layer-to-dielectric layer bonding, which is shortly referred to as a dielectric-to-dielectric bonding. The dielectric-to-dielectric bonding may refer to bonding of the bonding dielectric layers.

As described above, the semiconductor device 300, 310, 300A and 310A may include a memory cell array MCA disposed over the front side of the first substrate W10; a back-side interconnection structure BSPDN disposed at a higher level than the memory cell array MCA; a second substrate W20 having a front side FS facing the memory cell array MCA and a back side BS facing the back-side interconnection structure BSPDN; a control circuit including at least one or more transistors disposed over the front side FS of the second substrate W20; and a multi-level metal line MLM including at least one or more metal lines coupled to the control circuit. The back-side interconnection structure BSPDN includes a power interconnection line PIL embedded inside on the side of the front side FS of the second substrate W20; a power via PM1C passing through the back side BS of the second substrate W20 to be coupled to the power interconnection line PIL; a power contact plug PILC coupled to the power interconnection line PIL and the control circuit; and a power level spacer SP formed on the sidewall of the power interconnection line and the power via.

As described above, the semiconductor device 300, 310, 300A and 310A may have a structure in which the memory cell array MCA, the peripheral circuit PERI, and the back-side interconnection structure BSPDN are vertically stacked. The memory cell array MCA may be disposed at a lower level than the control circuits CL, SA and SWD. the post-multi-level metal line PMLM of the back-side interconnection structure BSPDN may be disposed at a higher level than the control circuits CL, SA and SWD. Power may be directly supplied from the back-side interconnection structure BSPDN to the control circuits CL, SA and SWD. Accordingly, a path for supplying the power from the back-side interconnection structure BSPDN to the control circuits CL, SA and SWD may become short. The power supply path may include the post-multi-level metal line PMLM, the power via PM1C, the power contact plug PILC, the power interconnection line PIL, the first level metal line MT1, and the first level metal contact plug M1C. The method for supplying power to the control circuits CL, SA and SWD of the peripheral circuit PERI may be a top-down power supply.

The memory cell array MCA and the peripheral circuit PERI may be bonded by a wafer bonding process. The memory cell array MCA and the peripheral circuit PERI may be bonded by a wafer bonding structure WBD. The wafer bonding structure WBD may improve the degree of integration, such as overcoming the process limitations and maximizing the net die.

When the wafer bonding process is applied, the back-side interconnection structure BSPDN may be disposed on the back side BS of the second substrate W20. Therefore, the power consumption and current resistance of the semiconductor device 300, 310, 300A and 310A may be reduced.

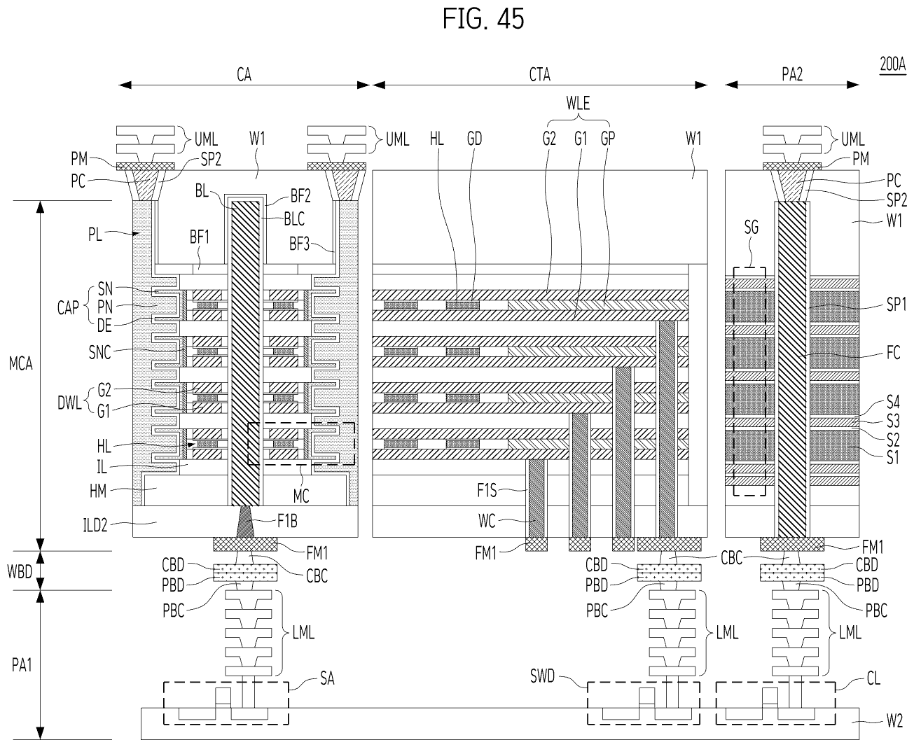

FIG. 45 schematically illustrate a semiconductor device in accordance with another embodiment of the present disclosure. The semiconductor device 200A of FIG. 45 may be similar to the semiconductor device 200 of FIG. 3. Hereinafter, overlapping descriptions of components identical to those shown in FIG. 3 will be simplified or omitted.

Referring to FIG. 45, the semiconductor device 200A may include a memory cell array MCA, a peripheral circuit region PA1, and a dummy region PA2. The memory cell array MCA and the dummy region PA2 may be disposed at a higher level than the peripheral circuit region PA1. The dummy region PA2 may be horizontally spaced apart from the memory cell array MCA. For the detailed description of the memory cell array MCA of FIG. 3, FIGS. 2A to 2D may be referred to.

The memory cell array MCA and the dummy region PA2 may be formed on a first substrate W1.

The peripheral circuit region PA1 may be formed on a second substrate W2. The memory cell array MCA may include a three-dimensional array of memory cells MC. For the detailed description of the memory cells MC, FIGS. 1A to 1C may be referred to. Each memory cell MC may include a first conductive line BL, a switching element TR, and a data storage element CAP.

The memory cell array MCA may include a first region CA and a second region CTA. The first region CA may have memory cells MC formed therein, and the second region CTA may have cell contact plugs WC formed therein. In the second region CTA, a stair-less pad portion WLE of the second conductive lines DWL may be disposed, and the second conductive lines DWL of the stair-less pad portion WLE may be coupled to the cell contact plugs WC. The stair-less pad portion WLE may include a vertical stack of pad portions, and respective pad portion of the stair-less pad portion WLE may include an upper horizontal line G1, a lower horizontal line G2, and a pad GP between the upper horizontal line G1 and lower horizontal line G2. The pad portions of the stair-shaped pad portion WLE may have the same horizontal length. The semiconductor device 200 of FIG. 3 may include a stair-shaped pad portion, and the semiconductor device 200A of FIG. 45 may include a stair-less pad portion.

The peripheral circuit region PA1 may be coupled to the memory cell array MCA. The peripheral circuit region PA1 may be disposed at a lower level than the memory cell array MCA. The first substrate W1 is flipped to bond the memory cell array MCA and the peripheral circuit region PA1. The peripheral circuit region PA1 may include one or more control circuits for driving the memory cell array MCA. For example, the peripheral circuit region PA1 may include sub-word line drivers SWD, a sense amplifier SA and a peripheral control circuit CL. The first conductive lines BL of the memory cell array MCA may be coupled to the sense amplifier SA.

The peripheral circuit region PA1 and the memory cell array MCA may be coupled to each other by a bonding structure WBD. The peripheral circuit region PA1 and the dummy region PA2 may be coupled to each other by a bonding structure WBD and a first multi-layer level interconnection LML. The bonding structure WBD may include a plurality of bonding pads CBD and PBD. The peripheral circuit region PA1 and the memory cell array MCA may be coupled to each other by the bonding structure WBD and the first multi-layer level interconnection LML. The bonding pads CBD and PBD may include first bonding pads CBD and second bonding pads PBD. The first bonding pads CBD and the second bonding pads PBD may be coupled to each other by wafer bonding. First bonding contact plugs CBC may be coupled to the first bonding pads CBD. Second bonding contact plugs PBC may be coupled to the second bonding pads PBD.

The first conductive lines BL of the memory cell array MCA may be coupled to the first bonding pads CBD and the first bonding contact plugs CBC through the front level interconnection FM1. The cell contact plugs WC of the memory cell array MCA may be coupled to the first bonding pads CBD and the first bonding contact plugs CBC through the front level interconnection FM1. Sidewall spacers F1S may be formed on the sidewalls of the first front contact plugs F1C. The sidewall spacers F1S may include a dielectric material. The common plate PL of the data storage elements CAP of the memory cell array MCA may be coupled to a second multi-layer level interconnection UML through a nano-through silicon via PC and a post-level interconnection PM. The nano-through silicon vias PC may penetrate the back side of the first substrate W1. Nano level spacers SP2 may be formed on the sidewalls of the nano-through silicon vias PC. The nano level spacers SP2 may be disposed between the nano-through silicon vias PC and the first substrate W1.

The dummy region PA2 may include a dummy stack SG, a stack level plug FC passing through the dummy stack SG, and a stack level spacer SP1 formed on the sidewall of the stack level plug FC. The stack level spacer SP1 may include a dielectric material. The dummy stack SG may include silicon layers S1 and S3 and silicon germanium layers S2 and S4.

The stack level spacers SP1 may be disposed between the stack level plugs FC and the dummy stack SG. A stack of the silicon layers S1 and S3 and the silicon germanium layers S2 and S4 may be disposed around the stack level plugs FC and the stack level spacers SP1. The vertical height of the stack level plug FC may be greater than the vertical height of the nano-through silicon via PC.

The second multi-layer level interconnection UML may be coupled to an upper portion of the stack level plug FC. The front level interconnection FM1 may be coupled to a lower portion of the stack level plug FC. The front level interconnection FM1 may be coupled to the first bonding contact plugs CBC and the first bonding pads CBD. The peripheral control circuit CL may be coupled to the second bonding contact plugs PBC and the second bonding pads PBD through the first multi-layer level interconnection LML.

The sub-word line drivers SWD and the sense amplifier SA may be coupled to the second bonding contact plugs PBC and the second bonding pads PBD through the first multi-layer level interconnection LML.

According to the embodiment of the present disclosure, spacers may be formed on the sidewalls of the stack level plugs disposed in the dummy region, thereby preventing short circuits between the neighboring structures.

While the embodiments of the present disclosure have been described with respect to the specific embodiments of the present disclosure, it will be apparent to those skilled in the art that various changes and modifications may be made without departing from the spirit and scope of the disclosure as defined in the following claims. Furthermore, the embodiments may be combined to form additional embodiments.

What is claimed is:

1. A semiconductor device comprising:
a memory cell array disposed over the peripheral circuit region;
a dummy region including a dummy stack that is spaced apart horizontally from the memory cell array;
a peripheral circuit region disposed at a lower level than the memory cell array and dummy region;
a stack level plug passing through the dummy stack; and
a stack level spacer formed on a sidewall of the stack level plug.

2. The semiconductor device of claim 1, wherein the dummy region further comprising:
a substrate including a front side and a back side;
a nano-through silicon via passing through the substrate and coupled to an upper portion of the stack level plug; and
a nano-level spacer formed on a sidewall of the nano-through silicon via,
wherein the dummy stack is formed on the front side of the substrate, and the substrate is flipped over so that the dummy stack and the peripheral circuit region face each other.

3. The semiconductor device of claim 2, wherein a vertical height of the stack level plug is greater than a vertical height of the nano-through silicon via.

4. The semiconductor device of claim 1, wherein the dummy stack includes
a plurality of silicon layers and a plurality of silicon germanium layers that are alternately stacked.

5. The semiconductor device of claim 1, wherein the peripheral circuit region includes
a plurality of control circuits for driving the memory cell array.

6. The semiconductor device of claim 1, wherein the memory cell array includes a plurality of memory cells that are stacked vertically, and
wherein each of the memory cells includes:
a horizontal layer that is oriented horizontally;
a first conductive line that is oriented vertically while being coupled to a first side of the horizontal layer;
a second conductive line that is oriented horizontally while crossing the horizontal layer; and
a data storage element that is coupled to a second side of the horizontal layer.

7. The semiconductor device of claim 6, wherein second conductive lines of the memory cell array include
a stair-shaped pad portion.

8. The semiconductor device of claim 7, wherein the pad portion includes:
an upper horizontal line;
a lower horizontal line; and
a pad between the upper horizontal line and the lower horizontal line.

9. The semiconductor device of claim 6, wherein second conductive lines of the memory cell array include
a stair-less pad portion.

10. The semiconductor device of claim 1, further comprising:
a bonding structure disposed
between the peripheral circuit region and the memory cell array, and
between the peripheral circuit region and the dummy region.

11. The semiconductor device of claim 10, wherein the bonding structure includes:
first bonding pads respectively coupled to the memory cell array and the stack level plug; and
a second bonding pad coupled to the peripheral circuit region.

12. A method for fabricating a semiconductor device, the method comprising:
forming a memory cell array and a dummy stack over a first substrate, the memory cell array and the dummy stack spaced apart from each other horizontally;
forming a stack level contact hole to penetrate the dummy stack;
forming a stack level spacer on a sidewall of the stack level contact hole; and
forming a stack level plug over the stack level spacer to fill the stack level contact hole.

13. The method of claim 12, wherein the memory cell array includes a plurality of memory cells that are stacked vertically, and
wherein each of the memory cells includes:
a horizontal layer that is oriented horizontally;
a first conductive line that is oriented vertically while being coupled to a first side of the horizontal layer;
a second conductive line that is oriented horizontally while crossing the horizontal layer; and
a data storage element coupled to a second side of the horizontal layer.

14. The method of claim 12, wherein forming the memory cell array and the dummy stack that are spaced apart from each other horizontally over the first substrate includes:
forming a stack body over the first substrate; and
replacing a first portion of the stack body with a cell mold, and
wherein a second portion of the stack body remains as the dummy stack.

15. The method of claim 12, further comprising:
forming a plurality of control circuits over a second substrate;
forming first bonding pads respectively coupled to the memory cell array and the stack level plug;
forming second bonding pads coupled to the control circuits; and
wafer-bonding the first bonding pads and the second bonding pads by turning over the first substrate.

16. The method of claim 15, further comprising:
after wafer-bonding the first bonding pads and the second bonding pads,
forming a nano-through hole to penetrate a back side of the first substrate and to expose the stack level plug;
forming a nano level spacer on a sidewall of the nano-through hole;
forming a nano-through silicon via to fill the nano-through hole over the nano level spacer; and
forming an upper level interconnection over the nano-through silicon via.

17. The method of claim 15, further comprising:
before forming the first bonding pads respectively coupled to the memory cell array and the stack level plug,
forming a lower level interconnection to be coupled to the stack level plug; and
forming a first bonding contact plug over the lower level interconnection.
